(19) United States
(12) Patent Application Publication
(10) Pub. No.: US 2023/0126558 A1
(43) Pub. Date: Apr. 27, 2023

(54) PHOTOVOLTAIC MODULES FOR COMMERCIAL ROOFING

(71) Applicant: GAF Energy LLC, Parsippany, NJ (US)

(72) Inventors: Thierry Nguyen, San Francisco, CA (US); Gabriela Bunea, San Jose, CA (US); Richard Perkins, San Jose, CA (US); David Kavulak, San Francisco, CA (US)

(73) Assignee: GAF Energy LLC, Parsippany, NJ (US)

(21) Appl. No.: 18/088,314

(22) Filed: Dec. 23, 2022

Related U.S. Application Data
(63) Continuation-in-part of application No. 17/900,604, filed on Aug. 31, 2022.
(60) Provisional application No. 63/239,772, filed on Sep. 1, 2021.

(51) Int. Cl. H01L 31/049; H01L 31/048; H02S 20/23

(52) U.S. Cl. CPC H01L 31/049; H01L 31/0481; H02S 20/23

(57) ABSTRACT

A roll, comprising: a laminate, comprising: a plurality of solar cells, wherein the plurality of solar cells comprises: a first solar cell, a second solar cell, and a third solar cell, wherein the first solar cell and the second solar cell are separated in a first direction by a first distance, wherein the second solar cell and the third solar cell are separated in the first direction by the first distance, and wherein each of the first, second, and third solar cells comprises: a width in the first direction, and a length in a second direction, wherein the second direction is perpendicular to the first direction; a first encapsulant, wherein the first encapsulant encapsulates the plurality of solar cells, and wherein the first encapsulant includes a first surface and a second surface opposite the first surface; a frontsheet, wherein the frontsheet includes a first surface and a second surface opposite the first surface of the frontsheet, wherein the second surface of the frontsheet is adjacent the first surface of the first encapsulant; and a backsheet, wherein the backsheet includes a first surface and a second surface opposite the first surface of the backsheet, wherein the first surface of the backsheet is adjacent the second surface of the first encapsulant, and wherein the widths of the first, second, and third solar cells, and the first and second distances are sized to permit at least a portion of the first surface of the frontsheet to be juxtaposed circumferentially with at least a portion of the second surface of the backsheet.

### CROSS-REFERENCE TO RELATED APPLICATIONS

This application is a Continuation-in-Part application relating to and claiming the benefit of commonly-owned, co-pending U.S. Non-Provisional patent application Ser. No. 17/900,604, filed Aug. 31, 2022, entitled “PHOTOVOLTAIC MODULES FOR COMMERCIAL ROOFING,” which is a Section 111(a) application relating to and claiming the benefit of commonly-owned, U.S. Provisional Patent Application Ser. No. 63/239,772, filed Sep. 1, 2021, entitled “PHOTOVOLTAIC MODULES FOR COMMERCIAL ROOFING,” the contents of which are incorporated herein by reference in their entireties.

### FIELD OF THE INVENTION

The present invention relates to photovoltaic modules, and, more particularly, photovoltaic modules for commercial roofing.

### BACKGROUND

Photovoltaic systems having solar panels are commonly installed on roofing of structures. What is needed are photovoltaic modules that are configured to be installed on commercial roofing systems.

### SUMMARY

In some embodiments, a system includes a roof deck, wherein the roof deck includes a slope of 0.25 inch to 3 inches per foot, wherein the roof deck includes a roofing membrane, and wherein the roofing membrane is composed of a first material; and at least one photovoltaic module installed on the roof deck, the photovoltaic module including at least one solar cell an encapsulant encapsulating the at least one solar cell, wherein the encapsulant includes a first surface and a second surface opposite the first surface, a frontsheet juxtaposed with the first surface of the encapsulant, and a backsheet juxtaposed with the second surface of the encapsulant, wherein the backsheet includes a head flap located at a first end of the backsheet, and a bottom flap located at a second end of the backsheet opposite the first end, wherein the backsheet is composed of the first material, wherein at least a first portion of the head flap is attached to the roofing membrane, and wherein at least a second portion of the bottom flap is attached to the roofing membrane.

In some embodiments, the first material is composed of a polymeric material. In some embodiments, the first material is composed of thermoplastic polyolefin (TPO). In some embodiments, the head flap and the bottom flap are attached to the roofing membrane by an adhesive. In some embodiments, the head flap and the bottom flap are attached to the roofing membrane by thermal bonding. In some embodiments, the head flap and the bottom flap are attached to the roofing membrane by ultrasonic welding. In some embodiments, the backsheet includes a first side flap located at a first side of the photovoltaic module and a second side flap located at a second side of the photovoltaic module opposite the first side, wherein at least a third portion of the first side flap is attached to the roofing membrane and at least a fourth portion of the second side flap is attached to the roofing membrane.

In some embodiments, the backsheet includes a first surface and a second surface opposite the first surface of the backsheet, and wherein the first surface of the backsheet is juxtaposed with the second surface of the encapsulant. In some embodiments, the second surface of the second portion of the bottom flap is attached to the roofing membrane. In some embodiments, the second surface of the first portion of the head flap is attached to the roofing membrane. In some embodiments, the first surface of the first portion of the head flap is attached to the roofing membrane. In some embodiments, the head flap includes a free end, wherein the free end of the head flap is folded relative to itself and forms a rounded end. In some embodiments, the rounded end includes a first portion juxtaposed with the roofing membrane and a second portion relative to the roofing membrane, wherein the second portion of the rounded end is elevated relative to the roofing membrane. In some embodiments, the first surface of at least the first portion of the rounded end is attached to the roofing membrane. In some embodiments, the second portion of the rounded end is sloped 0.1 degrees to 15 degrees.

In some embodiments, the system further includes at least one support member located intermediate a corresponding one of the at least one photovoltaic module and the roofing membrane, and wherein a portion of the at least one photovoltaic module is elevated relative to the roofing membrane. In some embodiments, the at least one solar cell includes a first plurality of solar cells arranged in a first array, and a second plurality of solar cells arranged in a second array, wherein the at least one photovoltaic module includes a first section, a second section, and a region located intermediate the first section and the second section, wherein the first array is located within the first section, wherein the second array is located within the second section, wherein the at least one support member is juxtaposed with the region.

In some embodiments, the at least one support member includes a rod. In some embodiments, the at least one support member is composed of thermoplastic polyolefin (TPO). In some embodiments, each of the first section and the second section is elevated relative to the roofing membrane, wherein the first section is sloped 0.1 degrees to 15 degrees, and wherein the second section is sloped 0.1 degrees to 15 degrees.

In some embodiments, the present invention provides a roll that comprises a laminate, which comprises: a plurality of solar cells, wherein the plurality of solar cells comprises a first solar cell, a second solar cell, and a third solar cell, wherein the first solar cell and the second solar cell are separated in a first direction by a first distance, wherein the second solar cell and the third solar cell are separated in the first direction by the first distance, and wherein each of the first, second, and third solar cells comprises: a width in the first direction, and a length in a second direction, wherein the second direction is perpendicular to the first direction; a first encapsulant, wherein the first encapsulant encapsulates the plurality of solar cells, and wherein the first encapsulant includes a first surface and a second surface opposite the first surface; a frontsheet, wherein the frontsheet includes a first surface and a second surface opposite the first surface of the frontsheet, wherein the second surface of the frontsheet is adjacent the first surface of the first encapsulant; and a backsheet, wherein the backsheet includes a first surface and a second surface opposite the first surface of the backsheet, wherein the first surface of the backsheet is adjacent the second surface of the first encapsulant, and wherein the widths of the first, second, and third solar cells, and the first and second distances are sized to permit at least a portion of the first surface of the frontsheet to be juxtaposed circumferentially with at least a portion of the second surface of the backsheet.

In some embodiments, the backsheet comprises a thermoplastic polyolefin.

In some embodiments, the at least a portion of the frontsheet contacts the at least a portion of the backsheet.

In some embodiments, the roll further comprises a longitudinal axis, wherein the first direction is perpendicular to the longitudinal axis, and wherein the second direction is parallel to the longitudinal axis.

In some embodiments, the backsheet contacts the second surface of the first encapsulant.

In some embodiments, the frontsheet contacts the first surface of the first encapsulant.

In some embodiments, the frontsheet comprises a transparent material.

In some embodiments, the transparent material comprises at least one of polymer and glass.

In some embodiments, the laminate further comprises: a support layer, wherein the support layer is adjacent the second surface of the first encapsulant; and a second encapsulant, wherein the second encapsulant is between the support layer and the backsheet.

In some embodiments, each of the first and second encapsulants comprises a same material.

In some embodiments, the present invention provides a method, comprising: obtaining a roll, the roll comprising: a laminate, comprising: a plurality of solar cells, wherein the plurality of solar cells comprises a first solar cell, a second solar cell, and a third solar cell, wherein the first solar cell and the second solar cell are separated in a first direction by a first distance, wherein the second solar cell and the third solar cell are separated in the first direction by the first distance, and wherein each of the first, second, and third solar cells comprises: a width in the first direction, and a length in a second direction, wherein the second direction is perpendicular to the first direction; a first encapsulant, wherein the first encapsulant encapsulates the plurality of solar cells, and wherein the first encapsulant includes a first surface and a second surface opposite the first surface; a frontsheet, wherein the frontsheet includes a first surface and a second surface opposite the first surface of the frontsheet, wherein the second surface of the frontsheet is adjacent the first surface of the first encapsulant; and a backsheet, wherein the backsheet includes a first surface and a second surface opposite the first surface of the backsheet, wherein the first surface of the backsheet is adjacent the second surface of the first encapsulant, and wherein the widths of the first, second, and third solar cells, and the first and second distances are sized to permit at least a portion of the first surface of the frontsheet to be juxtaposed circumferentially with at least a portion of the second surface of the backsheet; and unrolling the roll so as to install the laminate on a roof deck, wherein the second surface of the backsheet is juxtaposed with a surface of the roof deck.

In some embodiments, the unrolling the roll comprises unrolling the roll so as to install the laminate directly on the roof deck without any intervening member between the laminate and the roof deck.

In some embodiments, the method further comprises welding the laminate to the roof deck.

In some embodiments, the roof deck is a flat roof deck.

In some embodiments, the roof deck is a sloped roof deck.

### BRIEF DESCRIPTION OF THE DRAWINGS

FIGS. 1A and 1B are schematic views of some embodiments of a photovoltaic module;

FIG. 2A is a side elevational view of some embodiments of a photovoltaic module attached to a roof;

FIG. 2B is a schematic view of some embodiments of a photovoltaic module;

FIG. 3 is a top plan view the photovoltaic module shown in FIG. 2B;

FIG. 4 is a top plan view of the photovoltaic module shown in FIG. 3, but including an electrical connector;

FIGS. 5A and 5B illustrate some embodiments of a photovoltaic module;

FIG. 6 is a top plan view of the photovoltaic module shown in FIG. 5A;

FIG. 7 is a top plan view of the photovoltaic module shown in FIG. 6, but including an electrical connector;

FIGS. 8A through 8E illustrate some embodiments of a photovoltaic module;

FIG. 9 is a top plan view of some embodiments of a photovoltaic module;

FIG. 10 is a side elevational view of some embodiments of a photovoltaic module;

FIGS. 11A and 11B and schematic views of some embodiments of a photovoltaic module;

FIG. 12 is a side elevational view of some embodiments of a photovoltaic module; and

FIG. 13 is a schematic view of some embodiments of a photovoltaic module.

### DETAILED DESCRIPTION

The present invention will be further explained with reference to the attached drawings, wherein like structures are referred to by like numerals throughout the several views. The drawings shown are not necessarily to scale, with emphasis instead generally being placed upon illustrating the principles of the present invention. Further, some features may be exaggerated to show details of particular components.

The figures constitute a part of this specification and include illustrative embodiments of the present invention and illustrate various objects and features thereof. Further, the figures are not necessarily to scale, some features may be exaggerated to show details of particular components. In addition, any measurements, specifications and the like shown in the figures are intended to be illustrative, and not restrictive. Therefore, specific structural and functional details disclosed herein are not to be interpreted as limiting, but merely as a representative basis for teaching one skilled in the art to variously employ the present invention.

Among those benefits and improvements that have been disclosed, other objects and advantages of this invention will become apparent from the following description taken in conjunction with the accompanying figures. Detailed embodiments of the present invention are disclosed herein; however, it is to be understood that the disclosed embodiments are merely illustrative of the invention that may be embodied in various forms. In addition, each of the examples given in connection with the various embodiments of the invention which are intended to be illustrative, and not restrictive.

Throughout the specification, the following terms take the meanings explicitly associated herein, unless the context clearly dictates otherwise. The phrases “in one embodiment” and “in some embodiments” as used herein do not necessarily refer to the same embodiment(s), though they may. Furthermore, the phrases “in another embodiment” and “in some other embodiments” as used herein do not necessarily refer to a different embodiment, although they may. Thus, as described below, various embodiments of the invention may be readily combined, without departing from the scope or spirit of the invention.

The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

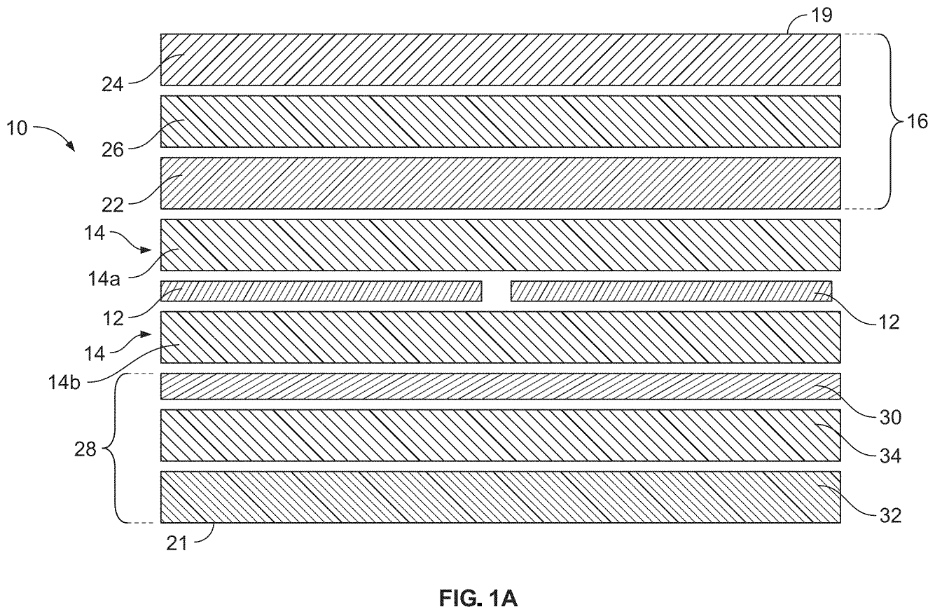

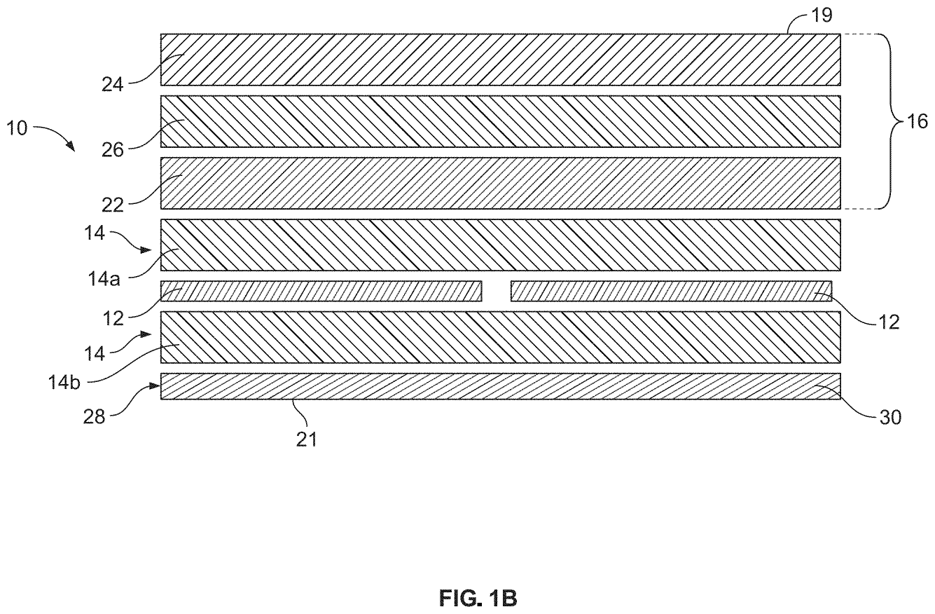

Referring to FIGS. 1A and 1B, in some embodiments, a photovoltaic module 10 includes at least one solar cell 12, an encapsulant 14 encapsulating the at least one solar cell 12, and a frontsheet 16 juxtaposed with the encapsulant 14. In some embodiments, the elements of the photovoltaic module 10 may be laminated with each other, such that the photovoltaic module 10 is in the form of a laminate. In some embodiments, the frontsheet 16 is juxtaposed with a first surface of the encapsulant 14. As used herein, the terms “encapsulating” and “encapsulates” mean to partially or fully envelope or enclose, and with respect to certain embodiments of the photovoltaic module 10, the at least one solar cell 12 is fully enveloped by or enclosed within the encapsulant 14, or partially enveloped by or enclosed within the encapsulant 14. In some embodiments, the encapsulant 14 encapsulates 50% to 99.9% of an exterior surface area of the at least one solar cell 12. In another embodiment, the encapsulant 14 encapsulates 55% to 99.9% of an exterior surface area of the at least one solar cell 12. In another embodiment, the encapsulant 14 encapsulates 60% to 99.9% of an exterior surface area of the at least one solar cell 12. In another embodiment, the encapsulant 14 encapsulates 65% to 99.9% of an exterior surface area of the at least one solar cell 12. In another embodiment, the encapsulant 14 encapsulates 70% to 99.9% of an exterior surface area of the at least one solar cell 12. In another embodiment, the encapsulant 14 encapsulates 75% to 99.9% of an exterior surface area of the at least one solar cell 12. In another embodiment, the encapsulant 14 encapsulates 80% to 99.9% of an exterior surface area of the at least one solar cell 12. In another embodiment, the encapsulant 14 encapsulates 85% to 99.9% of an exterior surface area of the at least one solar cell 12. In another embodiment, the encapsulant 14 encapsulates 90% to 99.9% of an exterior surface area of the at least one solar cell 12. In another embodiment, the encapsulant 14 encapsulates 95% to 99.9% of an exterior surface area of the at least one solar cell 12.

In another embodiment, the encapsulant 14 encapsulates 50% to 95% of an exterior surface area of the at least one solar cell 12. In another embodiment, the encapsulant 14 encapsulates 55% to 95% of an exterior surface area of the at least one solar cell 12. In another embodiment, the encapsulant 14 encapsulates 60% to 95% of an exterior surface area of the at least one solar cell 12. In another embodiment, the encapsulant 14 encapsulates 65% to 95% of an exterior surface area of the at least one solar cell 12. In another embodiment, the encapsulant 14 encapsulates 70% to 95% of an exterior surface area of the at least one solar cell 12. In another embodiment, the encapsulant 14 encapsulates 75% to 95% of an exterior surface area of the at least one solar cell 12. In another embodiment, the encapsulant 14 encapsulates 80% to 95% of an exterior surface area of the at least one solar cell 12. In another embodiment, the encapsulant 14 encapsulates 85% to 95% of an exterior surface area of the at least one solar cell 12. In another embodiment, the encapsulant 14 encapsulates 90% to 95% of an exterior surface area of the at least one solar cell 12.

In another embodiment, the encapsulant 14 encapsulates 50% to 90% of an exterior surface area of the at least one solar cell 12. In another embodiment, the encapsulant 14 encapsulates 55% to 90% of an exterior surface area of the at least one solar cell 12. In another embodiment, the encapsulant 14 encapsulates 60% to 90% of an exterior surface area of the at least one solar cell 12. In another embodiment, the encapsulant 14 encapsulates 65% to 90% of an exterior surface area of the at least one solar cell 12. In another embodiment, the encapsulant 14 encapsulates 70% to 90% of an exterior surface area of the at least one solar cell 12. In another embodiment, the encapsulant 14 encapsulates 75% to 90% of an exterior surface area of the at least one solar cell 12. In another embodiment, the encapsulant 14 encapsulates 80% to 90% of an exterior surface area of the at least one solar cell 12. In another embodiment, the encapsulant 14 encapsulates 85% to 90% of an exterior surface area of the at least one solar cell 12.

In another embodiment, the encapsulant 14 encapsulates 50% to 85% of an exterior surface area of the at least one solar cell 12. In another embodiment, the encapsulant 14 encapsulates 55% to 85% of an exterior surface area of the at least one solar cell 12. In another embodiment, the encapsulant 14 encapsulates 60% to 85% of an exterior surface area of the at least one solar cell 12. In another embodiment, the encapsulant 14 encapsulates 65% to 85% of an exterior surface area of the at least one solar cell 12. In another embodiment, the encapsulant 14 encapsulates 70% to 85% of an exterior surface area of the at least one solar cell 12. In another embodiment, the encapsulant 14 encapsulates 75% to 85% of an exterior surface area of the at least one solar cell 12. In another embodiment, the encapsulant 14 encapsulates 80% to 85% of an exterior surface area of the at least one solar cell 12.

In another embodiment, the encapsulant 14 encapsulates 50% to 80% of an exterior surface area of the at least one solar cell 12. In another embodiment, the encapsulant 14 encapsulates 55% to 80% of an exterior surface area of the at least one solar cell 12. In another embodiment, the encapsulant 14 encapsulates 60% to 80% of an exterior surface area of the at least one solar cell 12. In another embodiment, the encapsulant 14 encapsulates 65% to 80% of an exterior surface area of the at least one solar cell 12. In another embodiment, the encapsulant 14 encapsulates 70% to 80% of an exterior surface area of the at least one solar cell 12. In another embodiment, the encapsulant 14 encapsulates 75% to 80% of an exterior surface area of the at least one solar cell 12.

In another embodiment, the encapsulant 14 encapsulates 50% to 75% of an exterior surface area of the at least one solar cell 12. In another embodiment, the encapsulant 14 encapsulates 55% to 75% of an exterior surface area of the at least one solar cell 12. In another embodiment, the encapsulant 14 encapsulates 60% to 75% of an exterior surface area of the at least one solar cell 12. In another embodiment, the encapsulant 14 encapsulates 65% to 75% of an exterior surface area of the at least one solar cell 12. In another embodiment, the encapsulant 14 encapsulates 70% to 75% of an exterior surface area of the at least one solar cell 12.

In another embodiment, the encapsulant 14 encapsulates 50% to 70% of an exterior surface area of the at least one solar cell 12. In another embodiment, the encapsulant 14 encapsulates 55% to 70% of an exterior surface area of the at least one solar cell 12. In another embodiment, the encapsulant 14 encapsulates 60% to 70% of an exterior surface area of the at least one solar cell 12. In another embodiment, the encapsulant 14 encapsulates 65% to 70% of an exterior surface area of the at least one solar cell 12.

In another embodiment, the encapsulant 14 encapsulates 50% to 65% of an exterior surface area of the at least one solar cell 12. In another embodiment, the encapsulant 14 encapsulates 55% to 65% of an exterior surface area of the at least one solar cell 12. In another embodiment, the encapsulant 14 encapsulates 60% to 65% of an exterior surface area of the at least one solar cell 12. In another embodiment, the encapsulant 14 encapsulates 50% to 60% of an exterior surface area of the at least one solar cell 12. In another embodiment, the encapsulant 14 encapsulates 55% to 60% of an exterior surface area of the at least one solar cell 12. In another embodiment, the encapsulant 14 encapsulates 55% to 60% of an exterior surface area of the at least one solar cell 12.

In some embodiments, the encapsulant 14 encapsulates 50% of an exterior surface area of the at least one solar cell 12. In another embodiment, the encapsulant 14 encapsulates 55% of the exterior surface area of the at least one solar cell 12. In another embodiment, the encapsulant 14 encapsulates 60% of the exterior surface area of the at least one solar cell 12. In another embodiment, the encapsulant 14 encapsulates 65% of the exterior surface area of the at least one solar cell 12. In another embodiment, the encapsulant 14 encapsulates 70% of the exterior surface area of the at least one solar cell 12. In another embodiment, the encapsulant 14 encapsulates 75% of the exterior surface area of the at least one solar cell 12. In another embodiment, the encapsulant 14 encapsulates 80% of the exterior surface area of the at least one solar cell 12. In another embodiment, the encapsulant 14 encapsulates 85% of the exterior surface area of the at least one solar cell 12. In another embodiment, the encapsulant 14 encapsulates 90% of the exterior surface area of the at least one solar cell 12. In another embodiment, the encapsulant 14 encapsulates 95% of the exterior surface area of the at least one solar cell 12. In another embodiment, the encapsulant 14 encapsulates 100% of the exterior surface area of the at least one solar cell 12.

In some embodiments, the encapsulant 14 has a thickness of 0.5 mm to 4 mm. In another embodiment, the encapsulant 14 has a thickness of 0.5 mm to 3.5 mm. In another embodiment, the encapsulant 14 has a thickness of 0.5 mm to 3 mm. In another embodiment, the encapsulant 14 has a thickness of 0.5 mm to 2.5 mm. In another embodiment, the encapsulant 14 has a thickness of 0.5 mm to 2 mm. In another embodiment, the encapsulant 14 has a thickness of 0.5 mm to 1.5 mm. In another embodiment, the encapsulant 14 has a thickness of 0.5 mm to 1 mm.

In some embodiments, the encapsulant 14 has a thickness of 1 mm to 4 mm. In another embodiment, the encapsulant 14 has a thickness of 1 mm to 3.5 mm. In another embodiment, the encapsulant 14 has a thickness of 1 mm to 3 mm. In another embodiment, the encapsulant 14 has a thickness of 1 mm to 2.5 mm. In another embodiment, the encapsulant 14 has a thickness of 1 mm to 2 mm. In another embodiment, the encapsulant 14 has a thickness of 1 mm to 1.5 mm. In some embodiments, the encapsulant 14 has a thickness of 1.5 mm to 4 mm. In another embodiment, the encapsulant 14 has a thickness of 1.5 mm to 3.5 mm. In another embodiment, the encapsulant 14 has a thickness of 1.5 mm to 3 mm. In another embodiment, the encapsulant 14 has a thickness of 1.5 mm to 2.5 mm. In another embodiment, the encapsulant 14 has a thickness of 1.5 mm to 2 mm.

In some embodiments, the encapsulant 14 has a thickness of 2 mm to 4 mm. In another embodiment, the encapsulant 14 has a thickness of 2 mm to 3.5 mm. In another embodiment, the encapsulant 14 has a thickness of 2 mm to 3 mm. In another embodiment, the encapsulant 14 has a thickness of 2 mm to 2.5 mm. In some embodiments, the encapsulant 14 has a thickness of 2.5 mm to 4 mm. In another embodiment, the encapsulant 14 has a thickness of 2.5 mm to 3.5 mm. In another embodiment, the encapsulant 14 has a thickness of 2.5 mm to 3 mm. In some embodiments, the encapsulant 14 has a thickness of 3 mm to 4 mm. In another embodiment, the encapsulant 14 has a thickness of 3 mm to 3.5 mm. In some embodiments, the encapsulant 14 has a thickness of 3.5 mm to 4 mm.

In some embodiments, the encapsulant 14 has a thickness of 0.5 mm. In some embodiments, the encapsulant 14 has a thickness of 0.6 mm. In some embodiments, the encapsulant 14 has a thickness of 0.7 mm. In some embodiments, the encapsulant 14 has a thickness of 0.8 mm. In some embodiments, the encapsulant 14 has a thickness of 0.9 mm. In some embodiments, the encapsulant 14 has a thickness of 1 mm. In some embodiments, the encapsulant 14 has a thickness of 1.5 mm. In some embodiments, the encapsulant 14 has a thickness of 2 mm. In some embodiments, the encapsulant 14 has a thickness of 2.5 mm. In some embodiments, the encapsulant 14 has a thickness of 3 mm. In some embodiments, the encapsulant 14 has a thickness of 3.5 mm. In some embodiments, the encapsulant 14 has a thickness of 4 mm.

In some embodiments, a first layer 14a of the encapsulant 14 has a thickness of 0.2 mm to 2 mm. In some embodiments, the first layer 14a of the encapsulant 14 has a thickness of 0.2 mm to 1.5 mm. In some embodiments, the first layer 14a of the encapsulant 14 has a thickness of 0.2 mm to 1 mm. In some embodiments, the first layer 14a of the encapsulant 14 has a thickness of 0.2 mm to 0.6 mm. In some embodiments, the first layer 14a of the encapsulant 14 has a thickness of 0.2 mm to 0.5 mm. In some embodiments, the first layer 14a of the encapsulant 14 has a thickness of 0.5 mm to 2 mm. In some embodiments, the first layer 14a of the encapsulant 14 has a thickness of 0.5 mm to 1.5 mm. In some embodiments, the first layer 14a of the encapsulant 14 has a thickness of 0.5 mm to 1 mm. In some embodiments, the first layer 14a of the encapsulant 14 has a thickness of 1 mm to 2 mm. In some embodiments, the first layer 14a of the encapsulant 14 has a thickness of 1 mm to 1.5 mm. In some embodiments, the first layer 14a of the encapsulant 14 has a thickness of 1.5 mm to 2 mm.

In some embodiments, the first layer 14a of the encapsulant 14 has a thickness of 0.2 mm. In some embodiments, the first layer 14a of the encapsulant 14 has a thickness of 0.3 mm. In some embodiments, the first layer 14a of the encapsulant 14 has a thickness of 0.4 mm. In some embodiments, the first layer 14a of the encapsulant 14 has a thickness of 0.45 mm. In some embodiments, the first layer 14a of the encapsulant 14 has a thickness of 0.5 mm. In some embodiments, the first layer 14a of the encapsulant 14 has a thickness of 0.6 mm. In some embodiments, the first layer 14a of the encapsulant 14 has a thickness of 1 mm. In some embodiments, the first layer 14a of the encapsulant 14 has a thickness of 1.5 mm. In some embodiments, the first layer 14a of the encapsulant 14 has a thickness of 2 mm. In some embodiments, the first layer 14a of the encapsulant 14 has a thickness of 2.5 mm. In some embodiments, the first layer 14a of the encapsulant 14 has a thickness of 3 mm. In some embodiments, the first layer 14a of the encapsulant 14 has a thickness of 3.5 mm. In some embodiments, the first layer 14a of the encapsulant 14 has a thickness of 4 mm.

In some embodiments, a second layer 14b of the encapsulant 14 has a thickness of 0.2 mm to 2 mm. In some embodiments, the second layer 14b of the encapsulant 14 has a thickness of 0.2 mm to 1.5 mm. In some embodiments, the second layer 14b of the encapsulant 14 has a thickness of 0.2 mm to 1 mm. In some embodiments, the second layer 14b of the encapsulant 14 has a thickness of 0.2 mm to 0.5 mm. In some embodiments, the second layer 14b of the encapsulant 14 has a thickness of 0.5 mm to 2 mm. In some embodiments, the second layer 14b of the encapsulant 14 has a thickness of 0.5 mm to 1.5 mm. In some embodiments, the second layer 14b of the encapsulant 14 has a thickness of 0.5 mm to 1 mm. In some embodiments, the second layer 14b of the encapsulant 14 has a thickness of 1 mm to 2 mm. In some embodiments, the second layer 14b of the encapsulant 14 has a thickness of 1 mm to 1.5 mm. In some embodiments, the second layer 14b of the encapsulant 14 has a thickness of 1.5 mm to 2 mm.

In some embodiments, the second layer 14b of the encapsulant 14 has a thickness of 0.2 mm. In some embodiments, the second layer 14b of the encapsulant 14 has a thickness of 0.3 mm. In some embodiments, the second layer 14b of the encapsulant 14 has a thickness of 0.4 mm. In some embodiments, the second layer 14b of the encapsulant 14 has a thickness of 0.45 mm. In some embodiments, the second layer 14b of the encapsulant 14 has a thickness of 0.5 mm. In some embodiments, the second layer 14b of the encapsulant 14 has a thickness of 1 mm. In some embodiments, the second layer 14b of the encapsulant 14 has a thickness of 1.5 mm. In some embodiments, the second layer 14b of the encapsulant 14 has a thickness of 2 mm. In some embodiments, the second layer 14b of the encapsulant 14 has a thickness of 2.5 mm. In some embodiments, the second layer 14b of the encapsulant 14 has a thickness of 3 mm. In some embodiments, the second layer 14b of the encapsulant 14 has a thickness of 3.5 mm. In some embodiments, the second layer 14b of the encapsulant 14 has a thickness of 4 mm.

In some embodiments, the thickness of the first layer 14a is equal to the thickness of the second layer 14b. In another embodiment, the thickness of the first layer 14a is different from the thickness of the second layer 14b.

In some embodiments, the encapsulant 14 may be made from polyolefins, ethyl vinyl acetates, ionomers, silicones, poly vinyl butyral, epoxies, polyurethanes, or combinations/hybrids thereof. In some embodiments, the encapsulant 14 is made from thermosetting polyolefin.

In some embodiments, the photovoltaic module 10 includes a first end 18, a second end 20 opposite the first end 18, a first surface 19 extending from the first end 18 to the second end 20, and a second surface 21 opposite the first surface 19 and extending from the first end 18 to the second end 20. In some embodiments, the first surface 19 is an upper, sun facing-side surface of the photovoltaic module 10, and the second surface 21 is a lower surface configured to face a roof deck on which the photovoltaic module 10 is installed on the roof deck.

In some embodiments, the at least one solar cell 12 includes a plurality of the solar cells 12. In some embodiments, the plurality of solar cells 12 includes two solar cells. In some embodiments, the plurality of solar cells 12 includes three solar cells. In some embodiments, the plurality of solar cells 12 includes four solar cells. In some embodiments, the plurality of solar cells 12 includes five solar cells. In some embodiments, the plurality of solar cells 12 includes six solar cells. In some embodiments, the plurality of solar cells 12 includes seven solar cells. In some embodiments, the plurality of solar cells 12 includes eight solar cells. In some embodiments, the plurality of solar cells 12 includes nine solar cells. In some embodiments, the plurality of solar cells 12 includes ten solar cells. In some embodiments, the plurality of solar cells 12 includes eleven solar cells. In some embodiments, the plurality of solar cells 12 includes twelve solar cells. In some embodiments, the plurality of solar cells 12 includes thirteen solar cells. In some embodiments, the plurality of solar cells 12 includes fourteen solar cells. In some embodiments, the plurality of solar cells 12 includes fifteen solar cells. In some embodiments, the plurality of solar cells 12 includes sixteen solar cells. In some embodiments, the plurality of solar cells 12 includes more than sixteen solar cells.

In some embodiments, the plurality of solar cells 12 is arranged in one row (i.e., one reveal). In another embodiment, the plurality of solar cells 12 is arranged in two rows (i.e., two reveals). In another embodiment, the plurality of solar cells 12 is arranged in three rows (i.e., three reveals). In another embodiment, the plurality of solar cells 12 is arranged in four rows (i.e., four reveals). In another embodiment, the plurality of solar cells 12 is arranged in five rows (i.e., five reveals). In another embodiment, the plurality of solar cells 12 is arranged in six rows (i.e., six reveals). In other embodiments, the plurality of solar cells 12 is arranged in more than six rows.

In some embodiments, the frontsheet 16 includes a glass layer 22 and a polymer layer 24 attached to a first surface of the glass layer 22. In some embodiments, the frontsheet 16 is juxtaposed with the first layer 14a of the encapsulant 14. In some embodiments, each of the encapsulant 14, the glass layer 22, and the polymer layer 24 is transparent. In some embodiments, the polymer layer 24 is attached to the glass layer 22 by an first adhesive layer 26. In some embodiments, the first adhesive layer 26 may include polyvinyl butyrate, acrylic, silicone, or polycarbonate. In another embodiment, the first adhesive layer 26 may include pressure sensitive adhesives. In another embodiment, the polymer layer 24 is attached to the glass layer 22 by thermal bonding. In another embodiment, the frontsheet 16 includes at least one of the glass layer 22 or the polymer layer 24. In some embodiments, the first adhesive layer 26 is transparent. As used herein, the term “transparent” means having a solar weighted transmittance of 80% or greater, and with respect to certain embodiments of the photovoltaic module 10, a transparent layer of the photovoltaic module has a solar weighted transmittance of 80% or greater. In another embodiment, the frontsheet 16 does not include the glass layer 22.

In some embodiments, the glass layer 22 has a thickness of 1 mm to 4 mm. In some embodiments, the glass layer 22 has a thickness of 1 mm to 3.5 mm. In some embodiments, the glass layer 22 has a thickness of 1 mm to 3 mm. In some embodiments, the glass layer 22 has a thickness of 1 mm to 2.5 mm. In some embodiments, the glass layer 22 has a thickness of 1 mm to 2 mm. In some embodiments, the glass layer 22 has a thickness of 1 mm to 1.5 mm. In some embodiments, the glass layer 22 has a thickness of 1.5 mm to 4 mm. In some embodiments, the glass layer 22 has a thickness of 1.5 mm to 3.5 mm. In some embodiments, the glass layer 22 has a thickness of 1.5 mm to 3 mm. In some embodiments, the glass layer 22 has a thickness of 1 mm to 2.5 mm. In some embodiments, the glass layer 22 has a thickness of 1.5 mm to 2 mm.

In some embodiments, the glass layer 22 has a thickness of 2 mm to 4 mm. In some embodiments, the glass layer 22 has a thickness of 2 mm to 3.5 mm. In some embodiments, the glass layer 22 has a thickness of 2 mm to 3 mm. In some embodiments, the glass layer 22 has a thickness of 2 mm to 2.5 mm. In some embodiments, the glass layer 22 has a thickness of 2.5 mm to 4 mm. In some embodiments, the glass layer 22 has a thickness of 2.5 mm to 3.5 mm. In some embodiments, the glass layer 22 has a thickness of 2.5 mm to 3 mm. In some embodiments, the glass layer 22 has a thickness of 3 mm to 4 mm. In some embodiments, the glass layer 22 has a thickness of 3 mm to 3.5 mm. In some embodiments, the glass layer 22 has a thickness of 3.5 mm to 4 mm.

In some embodiments, the glass layer 22 has a thickness of 1 mm. In some embodiments, the glass layer 22 has a thickness of 1.5 mm. In some embodiments, the glass layer 22 has a thickness of 2 mm. In some embodiments, the glass layer 22 has a thickness of 2.5 mm. In some embodiments, the glass layer 22 has a thickness of 3 mm. In some embodiments, the glass layer 22 has a thickness of 3.5 mm. In some embodiments, the glass layer 22 has a thickness of 4 mm.

In some embodiments, the first adhesive layer 26 is composed of thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

In some embodiments, the first adhesive layer 26 has a thickness of 0.2 mm to 2 mm. In some embodiments, the first adhesive layer 26 has a thickness of 0.2 mm to 1.5 mm. In some embodiments, the first adhesive layer 26 has a thickness of 0.2 mm to 1 mm. In some embodiments, the first adhesive layer 26 has a thickness of 0.2 mm to 0.5 mm. In some embodiments, the first adhesive layer 26 has a thickness of 0.5 mm to 2 mm. In some embodiments, the first adhesive layer 26 has a thickness of 0.5 mm to 1.5 mm. In some embodiments, the first adhesive layer 26 has a thickness of 0.5 mm to 1 mm. In some embodiments, the first adhesive layer 26 has a thickness of 1 mm to 2 mm. In some embodiments, the first adhesive layer 26 has a thickness of 1 mm to 1.5 mm. In some embodiments, the first adhesive layer 26 has a thickness of 1.5 mm to 2 mm.

In some embodiments, the first adhesive layer 26 has a thickness of 0.2 mm. In some embodiments, the first adhesive layer 26 has a thickness of 0.3 mm. In some embodiments, the first adhesive layer 26 has a thickness of 0.4 mm. In some embodiments, the first adhesive layer 26 has a thickness of 0.45 mm. In some embodiments, the first adhesive layer 26 has a thickness of 0.5 mm. In some embodiments, the first adhesive layer 26 has a thickness of 1 mm. In some embodiments, the first adhesive layer 26 has a thickness of 1.5 mm. In some embodiments, the first adhesive layer 26 has a thickness of 2 mm. In some embodiments, the first adhesive layer 26 has a thickness of 2.5 mm. In some embodiments, the first adhesive layer 26 has a thickness of 3 mm. In some embodiments, the first adhesive layer 26 has a thickness of 3.5 mm. In some embodiments, the first adhesive layer 26 has a thickness of 4 mm.

In another embodiment, the first adhesive layer 26 has a thickness of 1 μm to 900 μm. In some embodiments, the first adhesive layer 26 has a thickness of 1 μm to 900 μm. In some embodiments, the first adhesive layer 26 has a thickness of 1 μm to 850 μm. In some embodiments, the first adhesive layer 26 has a thickness of 1 μm to 800 μm. In some embodiments, the first adhesive layer 26 has a thickness of 1 μm to 750 μm. In some embodiments, the first adhesive layer 26 has a thickness of 1 μm to 700 μm. In some embodiments, the first adhesive layer 26 has a thickness of 1 μm to 650 μm. In some embodiments, the first adhesive layer 26 has a thickness of 1 μm to 600 μm. In some embodiments, the first adhesive layer 26 has a thickness of 1 μm to 550 μm. In some embodiments, the first adhesive layer 26 has a thickness of 1 μm to 500 μm. In some embodiments, the first adhesive layer 26 has a thickness of 1 μm to 450 μm. In some embodiments, the first adhesive layer 26 has a thickness of 1 μm to 400 μm. In some embodiments, the first adhesive layer 26 has a thickness of 1 μm to 350 μm. In some embodiments, the first adhesive layer 26 has a thickness of 1 μm to 300 μm. In some embodiments, the first adhesive layer 26 has a thickness of 1 μm to 250 μm. In some embodiments, the first adhesive layer 26 has a thickness of 1 μm to 200 μm. In some embodiments, the first adhesive layer 26 has a thickness of 1 μm to 150 μm. In some embodiments, the first adhesive layer 26 has a thickness of 1 μm to 100 μm. In some embodiments, the first adhesive layer 26 has a thickness of 1 μm to 50 μm.

In some embodiments, the first adhesive layer 26 has a thickness of 50 μm to 900 μm. In some embodiments, the first adhesive layer 26 has a thickness of 50 μm to 850 μm. In some embodiments, the first adhesive layer 26 has a thickness of 50 μm to 800 μm. In some embodiments, the first adhesive layer 26 has a thickness of 50 μm to 750 μm. In some embodiments, the first adhesive layer 26 has a thickness of 50 μm to 700 μm. In some embodiments, the first adhesive layer 26 has a thickness of 50 μm to 650 μm. In some embodiments, the first adhesive layer 26 has a thickness of 50 μm to 600 μm. In some embodiments, the first adhesive layer 26 has a thickness of 50 μm to 550 μm. In some embodiments, the first adhesive layer 26 has a thickness of 50 μm to 500 μm. In some embodiments, the first adhesive layer 26 has a thickness of 50 μm to 450 μm. In some embodiments, the first adhesive layer 26 has a thickness of 50 μm to 400 μm. In some embodiments, the first adhesive layer 26 has a thickness of 50 μm to 350 μm. In some embodiments, the first adhesive layer 26 has a thickness of 50 μm to 300 μm. In some embodiments, the first adhesive layer 26 has a thickness of 50 μm to 250 μm. In some embodiments, the first adhesive layer 26 has a thickness of 50 μm to 200 μm. In some embodiments, the first adhesive layer 26 has a thickness of 50 μm to 150 μm. In some embodiments, the first adhesive layer 26 has a thickness of 50 μm to 100 μm.

In some embodiments, the first adhesive layer 26 has a thickness of 100 μm to 900 μm. In some embodiments, the first adhesive layer 26 has a thickness of 100 μm to 850 μm. In some embodiments, the first adhesive layer 26 has a thickness of 100 μm to 800 μm. In some embodiments, the first adhesive layer 26 has a thickness of 100 μm to 750 μm. In some embodiments, the first adhesive layer 26 has a thickness of 100 μm to 700 μm. In some embodiments, the first adhesive layer 26 has a thickness of 100 μm to 650 μm. In some embodiments, the first adhesive layer 26 has a thickness of 100 μm to 600 μm. In some embodiments, the first adhesive layer 26 has a thickness of 100 μm to 550 μm. In some embodiments, the first adhesive layer 26 has a thickness of 100 μm to 500 μm. In some embodiments, the first adhesive layer 26 has a thickness of 100 μm to 450 μm. In some embodiments, the first adhesive layer 26 has a thickness of 100 μm to 400 μm. In some embodiments, the first adhesive layer 26 has a thickness of 100 μm to 350 μm. In some embodiments, the first adhesive layer 26 has a thickness of 100 μm to 300 μm. In some embodiments, the first adhesive layer 26 has a thickness of 100 μm to 250 μm. In some embodiments, the first adhesive layer 26 has a thickness of 100 μm to 200 μm. In some embodiments, the first adhesive layer 26 has a thickness of 100 μm to 150 μm.

In some embodiments, the first adhesive layer 26 has a thickness of 150 μm to 900 μm. In some embodiments, the first adhesive layer 26 has a thickness of 150 μm to 850 μm. In some embodiments, the first adhesive layer 26 has a thickness of 150 μm to 800 μm. In some embodiments, the first adhesive layer 26 has a thickness of 150 μm to 750 μm. In some embodiments, the first adhesive layer 26 has a thickness of 150 μm to 700 μm. In some embodiments, the first adhesive layer 26 has a thickness of 150 μm to 650 μm. In some embodiments, the first adhesive layer 26 has a thickness of 150 μm to 600 μm. In some embodiments, the first adhesive layer 26 has a thickness of 150 μm to 550 μm. In some embodiments, the first adhesive layer 26 has a thickness of 150 μm to 500 μm. In some embodiments, the first adhesive layer 26 has a thickness of 150 μm to 450 μm. In some embodiments, the first adhesive layer 26 has a thickness of 150 μm to 400 μm. In some embodiments, the first adhesive layer 26 has a thickness of 150 μm to 350 μm. In some embodiments, the first adhesive layer 26 has a thickness of 150 μm to 300 μm. In some embodiments, the first adhesive layer 26 has a thickness of 150 μm to 250 μm. In some embodiments, the first adhesive layer 26 has a thickness of 150 μm to 200 μm.

In some embodiments, the first adhesive layer 26 has a thickness of 200 μm to 900 μm. In some embodiments, the first adhesive layer 26 has a thickness of 200 μm to 850 μm. In some embodiments, the first adhesive layer 26 has a thickness of 200 μm to 800 μm. In some embodiments, the first adhesive layer 26 has a thickness of 200 μm to 750 μm. In some embodiments, the first adhesive layer 26 has a thickness of 200 μm to 700 μm. In some embodiments, the first adhesive layer 26 has a thickness of 200 μm to 650 μm. In some embodiments, the first adhesive layer 26 has a thickness of 200 μm to 600 μm. In some embodiments, the first adhesive layer 26 has a thickness of 200 μm to 550 μm. In some embodiments, the first adhesive layer 26 has a thickness of 200 μm to 500 μm. In some embodiments, the first adhesive layer 26 has a thickness of 200 μm to 450 μm. In some embodiments, the first adhesive layer 26 has a thickness of 200 μm to 400 μm. In some embodiments, the first adhesive layer 26 has a thickness of 200 μm to 350 μm. In some embodiments, the first adhesive layer 26 has a thickness of 200 μm to 300 μm. In some embodiments, the first adhesive layer 26 has a thickness of 200 μm to 250 μm.

In some embodiments, the first adhesive layer 26 has a thickness of 250 μm to 900 μm. In some embodiments, the first adhesive layer 26 has a thickness of 250 μm to 850 μm. In some embodiments, the first adhesive layer 26 has a thickness of 250 μm to 800 μm. In some embodiments, the first adhesive layer 26 has a thickness of 250 μm to 750 μm. In some embodiments, the first adhesive layer 26 has a thickness of 250 μm to 700 μm. In some embodiments, the first adhesive layer 26 has a thickness of 250 μm to 650 μm. In some embodiments, the first adhesive layer 26 has a thickness of 250 μm to 600 μm. In some embodiments, the first adhesive layer 26 has a thickness of 250 μm to 550 μm. In some embodiments, the first adhesive layer 26 has a thickness of 250 μm to 500 μm. In some embodiments, the first adhesive layer 26 has a thickness of 250 μm to 450 μm. In some embodiments, the first adhesive layer 26 has a thickness of 250 μm to 400 μm. In some embodiments, the first adhesive layer 26 has a thickness of 250 μm to 350 μm. In some embodiments, the first adhesive layer 26 has a thickness of 250 μm to 300 μm.

In some embodiments, the first adhesive layer 26 has a thickness of 300 μm to 900 μm. In some embodiments, the first adhesive layer 26 has a thickness of 300 μm to 850 μm. In some embodiments, the first adhesive layer 26 has a thickness of 300 μm to 800 μm. In some embodiments, the first adhesive layer 26 has a thickness of 300 μm to 750 μm. In some embodiments, the first adhesive layer 26 has a thickness of 300 μm to 700 μm. In some embodiments, the first adhesive layer 26 has a thickness of 300 μm to 650 μm. In some embodiments, the first adhesive layer 26 has a thickness of 300 μm to 600 μm. In some embodiments, the first adhesive layer 26 has a thickness of 300 μm to 550 μm. In some embodiments, the first adhesive layer 26 has a thickness of 300 μm to 500 μm. In some embodiments, the first adhesive layer 26 has a thickness of 300 μm to 450 μm. In some embodiments, the first adhesive layer 26 has a thickness of 300 μm to 400 μm. In some embodiments, the first adhesive layer 26 has a thickness of 300 μm to 350 μm.

In some embodiments, the first adhesive layer 26 has a thickness of 350 μm to 900 μm. In some embodiments, the first adhesive layer 26 has a thickness of 350 μm to 850 μm. In some embodiments, the first adhesive layer 26 has a thickness of 350 μm to 800 μm. In some embodiments, the first adhesive layer 26 has a thickness of 350 μm to 750 μm. In some embodiments, the first adhesive layer 26 has a thickness of 350 μm to 700 μm. In some embodiments, the first adhesive layer 26 has a thickness of 350 μm to 650 μm. In some embodiments, the first adhesive layer 26 has a thickness of 350 μm to 600 μm. In some embodiments, the first adhesive layer 26 has a thickness of 350 μm to 550 μm. In some embodiments, the first adhesive layer 26 has a thickness of 350 μm to 500 μm. In some embodiments, the first adhesive layer 26 has a thickness of 350 μm to 450 μm. In some embodiments, the first adhesive layer 26 has a thickness of 350 μm to 400 μm.

In some embodiments, the first adhesive layer 26 has a thickness of 400 μm to 900 μm. In some embodiments, the first adhesive layer 26 has a thickness of 400 μm to 850 μm. In some embodiments, the first adhesive layer 26 has a thickness of 400 μm to 800 μm. In some embodiments, the first adhesive layer 26 has a thickness of 400 μm to 750 μm. In some embodiments, the first adhesive layer 26 has a thickness of 400 μm to 700 μm. In some embodiments, the first adhesive layer 26 has a thickness of 400 μm to 650 μm. In some embodiments, the first adhesive layer 26 has a thickness of 400 μm to 600 μm. In some embodiments, the first adhesive layer 26 has a thickness of 400 μm to 550 μm. In some embodiments, the first adhesive layer 26 has a thickness of 400 μm to 500 μm. In some embodiments, the first adhesive layer 26 has a thickness of 400 μm to 450 μm.

In some embodiments, the first adhesive layer 26 has a thickness of 450 μm to 900 μm. In some embodiments, the first adhesive layer 26 has a thickness of 450 μm to 850 μm. In some embodiments, the first adhesive layer 26 has a thickness of 450 μm to 800 μm. In some embodiments, the first adhesive layer 26 has a thickness of 450 μm to 750 μm. In some embodiments, the first adhesive layer 26 has a thickness of 450 μm to 700 μm. In some embodiments, the first adhesive layer 26 has a thickness of 450 μm to 650 μm. In some embodiments, the first adhesive layer 26 has a thickness of 450 μm to 600 μm. In some embodiments, the first adhesive layer 26 has a thickness of 450 μm to 550 μm. In some embodiments, the first adhesive layer 26 has a thickness of 450 μm to 500 μm.

In some embodiments, the first adhesive layer 26 has a thickness of 500 μm to 900 μm. In some embodiments, the first adhesive layer 26 has a thickness of 500 μm to 850 μm. In some embodiments, the first adhesive layer 26 has a thickness of 500 μm to 800 μm. In some embodiments, the first adhesive layer 26 has a thickness of 500 μm to 750 μm. In some embodiments, the first adhesive layer 26 has a thickness of 500 μm to 700 μm. In some embodiments, the first adhesive layer 26 has a thickness of 500 μm to 650 μm. In some embodiments, the first adhesive layer 26 has a thickness of 500 μm to 600 μm. In some embodiments, the first adhesive layer 26 has a thickness of 500 μm to 550 μm.

In some embodiments, the first adhesive layer 26 has a thickness of 550 μm to 900 μm. In some embodiments, the first adhesive layer 26 has a thickness of 550 μm to 850 μm. In some embodiments, the first adhesive layer 26 has a thickness of 550 μm to 800 μm. In some embodiments, the first adhesive layer 26 has a thickness of 550 μm to 750 μm. In some embodiments, the first adhesive layer 26 has a thickness of 550 μm to 700 μm. In some embodiments, the first adhesive layer 26 has a thickness of 550 μm to 650 μm. In some embodiments, the first adhesive layer 26 has a thickness of 550 μm to 600 μm.

In some embodiments, the first adhesive layer 26 has a thickness of 600 μm to 900 μm. In some embodiments, the first adhesive layer 26 has a thickness of 600 μm to 850 μm. In some embodiments, the first adhesive layer 26 has a thickness of 600 μm to 800 μm. In some embodiments, the first adhesive layer 26 has a thickness of 600 μm to 750 μm. In some embodiments, the first adhesive layer 26 has a thickness of 600 μm to 700 μm. In some embodiments, the first adhesive layer 26 has a thickness of 600 μm to 650 μm.

In some embodiments, the first adhesive layer 26 has a thickness of 650 μm to 900 μm. In some embodiments, the first adhesive layer 26 has a thickness of 650 μm to 850 μm. In some embodiments, the first adhesive layer 26 has a thickness of 650 μm to 800 μm. In some embodiments, the first adhesive layer 26 has a thickness of 650 μm to 750 μm. In some embodiments, the first adhesive layer 26 has a thickness of 650 μm to 700 μm. In some embodiments, the first adhesive layer 26 has a thickness of 700 μm to 900 μm. In some embodiments, the first adhesive layer 26 has a thickness of 700 μm to 850 μm. In some embodiments, the first adhesive layer 26 has a thickness of 700 μm to 800 μm. In some embodiments, the first adhesive layer 26 has a thickness of 700 μm to 750 μm. In some embodiments, the first adhesive layer 26 has a thickness of 750 μm to 900 μm. In some embodiments, the first adhesive layer 26 has a thickness of 750 μm to 850 μm. In some embodiments, the first adhesive layer 26 has a thickness of 750 μm to 800 μm. In some embodiments, the first adhesive layer 26 has a thickness of 800 μm to 900 μm. In some embodiments, the first adhesive layer 26 has a thickness of 800 μm to 850 μm. In some embodiments, the first adhesive layer 26 has a thickness of 850 μm to 900 μm.

In some embodiments, the first adhesive layer 26 has a thickness of 1 μm. In some embodiments, the first adhesive layer 26 has a thickness of 50 μm. In some embodiments, the first adhesive layer 26 has a thickness of 100 μm. In some embodiments, the first adhesive layer 26 has a thickness of 1 μm. In some embodiments, the first adhesive layer 26 has a thickness of 150 μm. In some embodiments, the first adhesive layer 26 has a thickness of 200 μm. In some embodiments, the first adhesive layer 26 has a thickness of 250 μm. In some embodiments, the first adhesive layer 26 has a thickness of 300 μm. In some embodiments, the first adhesive layer 26 has a thickness of 350 μm. In some embodiments, the first adhesive layer 26 has a thickness of 400 μm. In some embodiments, the first adhesive layer 26 has a thickness of 450 μm. In some embodiments, the first adhesive layer 26 has a thickness of 500 μm. In some embodiments, the first adhesive layer 26 has a thickness of 550 μm. In some embodiments, the first adhesive layer 26 has a thickness of 600 μm. In some embodiments, the first adhesive layer 26 has a thickness of 650 μm. In some embodiments, the first adhesive layer 26 has a thickness of 700 μm. In some embodiments, the first adhesive layer 26 has a thickness of 750 μm. In some embodiments, the first adhesive layer 26 has a thickness of 800 μm. In some embodiments, the first adhesive layer 26 has a thickness of 850 μm. In some embodiments, the first adhesive layer 26 has a thickness of 900 μm.

In some embodiments, the polymer layer 24 is composed of a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet is composed of fluoropolymers, acrylics, polyesters, silicones, polycarbonates, or combinations thereof. In other embodiments, the polymer layer 24 is composed of polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the polymer layer 24 is composed of a crosslinked polymeric material. In some embodiments, 50% to 99% of the polymer chains of the polymeric material are crosslinked.

In some embodiments, the polymer layer 24 has a thickness of 0.01 mm to 0.5 mm. In some embodiments, the polymer layer 24 has a thickness of 0.01 mm to 0.45 mm. In some embodiments, the polymer layer 24 has a thickness of 0.01 mm to 0.4 mm. In some embodiments, the polymer layer 24 has a thickness of 0.01 mm to 0.35 mm. In some embodiments, the polymer layer 24 has a thickness of 0.01 mm to 0.3 mm. In some embodiments, the polymer layer 24 has a thickness of 0.01 mm to 0.25 mm. In some embodiments, the polymer layer 24 has a thickness of 0.01 mm to 0.2 mm. In some embodiments, the polymer layer 24 has a thickness of 0.01 mm to 0.15 mm. In some embodiments, the polymer layer 24 has a thickness of 0.01 mm to 0.1 mm. In some embodiments, the polymer layer 24 has a thickness of 0.01 mm to 0.05 mm.

In some embodiments, the polymer layer 24 has a thickness of 0.05 mm to 0.5 mm. In some embodiments, the polymer layer 24 has a thickness of 0.05 mm to 0.45 mm. In some embodiments, the polymer layer 24 has a thickness of 0.05 mm to 0.4 mm. In some embodiments, the polymer layer 24 has a thickness of 0.05 mm to 0.35 mm. In some embodiments, the polymer layer 24 has a thickness of 0.05 mm to 0.3 mm. In some embodiments, the polymer layer 24 has a thickness of 0.05 mm to 0.25 mm. In some embodiments, the polymer layer 24 has a thickness of 0.05 mm to 0.2 mm. In some embodiments, the polymer layer 24 has a thickness of 0.05 mm to 0.15 mm. In some embodiments, the polymer layer 24 has a thickness of 0.05 mm to 0.1 mm.

In some embodiments, the polymer layer 24 has a thickness of 0.1 mm to 0.5 mm. In some embodiments, the polymer layer 24 has a thickness of 0.1 mm to 0.45 mm. In some embodiments, the polymer layer 24 has a thickness of 0.1 mm to 0.4 mm. In some embodiments, the polymer layer 24 has a thickness of 0.1 mm to 0.35 mm. In some embodiments, the polymer layer 24 has a thickness of 0.1 mm to 0.3 mm. In some embodiments, the polymer layer 24 has a thickness of 0.1 mm to 0.25 mm. In some embodiments, the polymer layer 24 has a thickness of 0.1 mm to 0.2 mm. In some embodiments, the polymer layer 24 has a thickness of 0.1 mm to 0.15 mm. In some embodiments, the polymer layer 24 has a thickness of 0.15 mm to 0.5 mm. In some embodiments, the polymer layer 24 has a thickness of 0.15 mm to 0.45 mm. In some embodiments, the polymer layer 24 has a thickness of 0.15 mm to 0.4 mm. In some embodiments, the polymer layer 24 has a thickness of 0.15 mm to 0.35 mm. In some embodiments, the polymer layer 24 has a thickness of 0.15 mm to 0.3 mm. In some embodiments, the polymer layer 24 has a thickness of 0.15 mm to 0.25 mm. In some embodiments, the polymer layer 24 has a thickness of 0.15 mm to 0.2 mm.

In some embodiments, the polymer layer 24 has a thickness of 0.2 mm to 0.5 mm. In some embodiments, the polymer layer 24 has a thickness of 0.2 mm to 0.45 mm. In some embodiments, the polymer layer 24 has a thickness of 0.2 mm to 0.4 mm. In some embodiments, the polymer layer 24 has a thickness of 0.2 mm to 0.35 mm. In some embodiments, the polymer layer 24 has a thickness of 0.2 mm to 0.3 mm. In some embodiments, the polymer layer 24 has a thickness of 0.2 mm to 0.25 mm. In some embodiments, the polymer layer 24 has a thickness of 0.25 mm to 0.5 mm. In some embodiments, the polymer layer 24 has a thickness of 0.25 mm to 0.45 mm. In some embodiments, the polymer layer 24 has a thickness of 0.25 mm to 0.4 mm. In some embodiments, the polymer layer 24 has a thickness of 0.25 mm to 0.35 mm. In some embodiments, the polymer layer 24 has a thickness of 0.25 mm to 0.3 mm.

In some embodiments, the polymer layer 24 has a thickness of 0.3 mm to 0.5 mm. In some embodiments, the polymer layer 24 has a thickness of 0.3 mm to 0.45 mm. In some embodiments, the polymer layer 24 has a thickness of 0.3 mm to 0.4 mm. In some embodiments, the polymer layer 24 has a thickness of 0.3 mm to 0.35 mm. In some embodiments, the polymer layer 24 has a thickness of 0.35 mm to 0.5 mm. In some embodiments, the polymer layer 24 has a thickness of 0.35 mm to 0.45 mm. In some embodiments, the polymer layer 24 has a thickness of 0.35 mm to 0.4 mm. In some embodiments, the polymer layer 24 has a thickness of 0.4 mm to 0.5 mm. In some embodiments, the polymer layer 24 has a thickness of 0.4 mm to 0.45 mm. In some embodiments, the polymer layer 24 has a thickness of 0.45 mm to 0.5 mm.

In some embodiments, the polymer layer 24 has a thickness of 0.01 mm. In some embodiments, the polymer layer 24 has a thickness of 0.05 mm. In some embodiments, the polymer layer 24 has a thickness of 0.1 mm. In some embodiments, the polymer layer 24 has a thickness of 0.15 mm. In some embodiments, the polymer layer 24 has a thickness of 0.2 mm. In some embodiments, the polymer layer 24 has a thickness of 0.25 mm. In some embodiments, the polymer layer 24 has a thickness of 0.3 mm. In some embodiments, the polymer layer 24 has a thickness of 0.35 mm. In some embodiments, the polymer layer 24 has a thickness of 0.4 mm. In some embodiments, the polymer layer 24 has a thickness of 0.45 mm. In some embodiments, the polymer layer 24 has a thickness of 0.5 mm.

In some embodiments, a backsheet 28 is juxtaposed with a second layer 14b of the encapsulant 14. In some embodiments, the backsheet 28 includes a first layer 30. In some embodiments, the backsheet 28 includes a second layer 32. In some embodiments, the first layer 30 is juxtaposed with the second layer 14b of the encapsulant 14. In some embodiments, the second layer 32 is juxtaposed with the first layer 30. In some embodiments, the backsheet 28 only includes the first layer 30 (see FIG. 1B). In some embodiments, the photovoltaic module 10 does not include the backsheet 28.

In some embodiments, the first layer 30 of the backsheet 28 is composed of a polymeric material. In some embodiments, the first layer 30 of the backsheet 28 is composed of polyethylene terephthalate (“PET”). In some embodiments, the first layer 30 of the backsheet 28 is composed of an acrylic such as polymethyl methacrylate (“PMMA”). In some embodiments, the first layer 30 of the backsheet 28 is composed of thermoplastic polyolefin (TPO). In some embodiments, the first layer 30 of the backsheet 28 includes of a single ply TPO roofing membrane. In other embodiments, non-limiting examples of TPO membranes are disclosed in U.S. Pat. No. 9,359,014 to Yang et al., which is incorporated by reference herein in its entirety. In another embodiment, the first layer 30 of the backsheet 28 is composed of polyvinyl chloride. In some embodiments, the first layer 30 of the backsheet 28 is composed of ethylene propylene diene monomer (EPDM) rubber. In some embodiments, the first layer 30 of the backsheet 28 is composed of polyvinyl chloride (PVC). In some embodiments, the first layer 30 of the backsheet 28 includes a flame retardant additive. In some embodiments, the flame retardant additive may be clays, nanoclays, silicas, carbon black, metal hydroxides such as aluminum hydroxide, metal foils, graphite, and combinations thereof. In some embodiments, the first layer 30 is white in color. In some embodiments, the first layer 30 is white TPO.

In some embodiments, the first layer 30 is composed of a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), (PTFE) and tetrafluoroethylene-hexafluoropropylene-vinylidene fluoride copolymers (THV), polyvinyl fluoride (PVF), or blends thereof. In an embodiment, the first layer 30 is composed of fluoropolymers, acrylics, polyesters, silicones, polycarbonates, or combinations thereof. In other embodiments, the first layer 30 is composed of polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide.

In some embodiments, the first layer 30 is composed of cyclopiazonic acid (CPA), chlorinated polyethylene resins (CPE), ethylene interpolymers (EIP), nitrile butadiene polymers (NBP), polyisobutylenes (PIB), atactic-polypropylene (APP), APP-modified bitumen, poly(styrene-butadiene-styrene) (SBS), styrene ethylene butylene styrene (SEBS), chlorosulfonated polyethylene rubbers (CSPE), polychloroprene (CR), extracellular region membranes (ECR), polycarbonate, nylon, polyvinyl acetate, polystyrene, polyurethane, epoxy and the like.

In some embodiments, the polymeric material may comprise, consist of, or consist essentially of at least one thermoplastic polymer, at least one recycled polymer, or any combination thereof. In some embodiments, the at least one thermoplastic polymer may comprise, consist of, or consist essentially of a polyolefin, a vinyl polymer, or any combination thereof. In some embodiments, the polyolefin may comprise, consist of, or consist essentially of polyethylene, polypropylene, or any combination thereof, such as, for example and without limitation, a copolymer of ethylene and propylene. In some embodiments, the polyolefin may comprise, consist of, or consist essentially of a copolymer of ethylene and an alpha-olefin, such as, for example and without limitation, ethylene and 1-octene, ethylene and 1-hexene, and ethylene and 1-butene. In some embodiments, the vinyl polymer may comprise, consist of, or consist essentially of a polyvinyl ester. In some embodiments, the vinyl polymer may comprise, consist of, or consist essentially of polyvinyl butyral (PVB). In some embodiments, the thermoplastic polymer may comprise, consist of, or consist essentially of a thermoplastic elastomer.

Some non-limiting examples of the polymeric materials (e.g., such as, one or more of thermoplastic polymers, polyolefins, vinyl polymers, polyvinyl esters, thermoplastic elastomers, recycled polymers, etc.) may include, without limitation, one or more of the following: polyethylenes (PE) (e.g., including, without limitation, one or more of raw low density polyethylene, recycled low density polyethylene (LDPE), linear low density polyethylene (LLDPE), and high density polyethylene (HDPE)), polypropylene (PP) (e.g., including, without limitation, one or more of isotactic polypropylene (IPP), atactic polypropylene/isotactic propylene (APP/IPP)), polystyrene, polyurethane (PU/TPU), polyurea, terpolymers (e.g., including, without limitation, a functionalized polymer with a reactive oxygen group), amorphous polyalpha olefins (APAO), amorphous polyolefins (APO), (e.g., including, without limitation, one or more of propylene homopolymers, copolymers of propylene and ethylene, copolymers of ethylene alpha-olefin, such as ethylene and 1-octene, ethylene and 1-hexene, and ethylene and 1-butene), polyolefin elastomers (POE), styrene/styrenic block copolymers (e.g., including, without limitation, one or more of styrenic block copolymers with a hydrogenated midblock of styrene-ethylene/butylene-styrene (SEBS), styrene-ethylene/propylene-styrene (SEPS), styrene-isoprene-styrene block copolymers (SIS), and styrene-butadiene-styrene block copolymers (SBS)), ethylene vinyl acetate (EVA), polyisobutylene, polybutadiene, oxidized polyethylene, epoxy thermoplastics, raw polyvinyl butyral (PVB), recycled polyvinyl butyral (rPVB), polyvinyl acetate (PVAC), poly(vinyl butyrate), poly(vinyl propionate), poly(vinyl formate), and copolymers of PVAC (e.g., including, without limitation, copolymers of PVAC and EVA). Some non-limiting examples of the at least one polymer (e.g., including, without limitation, thermoplastic polymers, polyolefins, vinyl polymers, polyvinyl esters, and thermoplastic elastomers) may include, without limitation, one or more of the following: Vistamaxx® 6102 and Vistamaxx® 8880, which are polypropylenes (e.g., isotactic polypropylene (IPP)) and which are available from ExxonMobil, Irving, Tex.; Elvaloy®, which is a terpolymer and which is available from Dow/DuPont, Wilmington, Del.; Fusabond®, which is a chemically modified ethylene acrylate copolymer, a modified polyethylene, or a combination thereof and which is available from Dow/DuPont, Wilmington, Del.; RT2304, which is an amorphous polyalpha olefin (APAO) and which is available from Rextac APAO Polymers LLC, Odessa, Tex.; Eastoflex® P1023, which is an amorphous polyolefin (APO) comprising a propylene homopolymer and which is available from Eastman Chemical Company, Kingsport, Tenn.; Eastoflex® E1060, which is an amorphous polyolefin (APO) comprising a copolymer of propylene and ethylene and which is available from Eastman Chemical Company, Kingsport, Tenn.; Eastoflex® M1025, which is an amorphous polyolefin (APO) that comprises a blend of propylene homopolymer and copolymers of propylene and ethylene and which is available from Eastman Chemical Company, Kingsport, Tenn.; Engage® 7487, which is a polyolefin elastomer (POE) and which is available from Dow Inc., Midland, Mich.; SEBS 1657, which is a linear triblock copolymer based on styrene and ethylene/butylene, namely, styrene-ethylene/butylene-styrene (SEBS) and which is available Kraton™ Corporation, Houston, Tex.; D0243, D0246, D1101, D1102, D1116, D1118, D1152, D1155, D1157, D1184, D1189, D1191, and D1194, which are styrene butadiene styrene block copolymers comprising blocks of styrene and butadiene and which is available Kraton™ Corporation, Houston, Tex.; PI131350, which is a polyisobutylene and which is available from TPC Group, Houston, Tex.; ethylene bis stearamide (EBS), which is available from ACME-Hardesty Company, Blue Bell, Pa.; IPP, which is available from Bay Polymer Corp., Fremont, Calif.; and recycled low density polyethylene, which is available from Avangard Innovative, Houston, Tex.

In some embodiments, the first layer 30 includes a non-asphalt (NAS) roofing material. In an embodiment, the NAS material includes a thermoplastic polymer. In some embodiments, the thermoplastic polymer includes at least one of a polyolefin, a vinyl polymer, and combinations thereof. In some embodiments, the polyolefin comprises one of (i) a polypropylene, (ii) a polyethylene, or (iii) a copolymer of propylene and ethylene. In an embodiment, the vinyl polymer is polyvinyl butyral (PVB). In some embodiments, the NAS material includes a filler. In an embodiment, the filler includes at least one of an organic filler, an inorganic mineral filler, or combinations thereof. In an embodiment, the filler is at least one of calcium carbonate, barium sulfate, calcium sulfate, talc, limestone, perlite, silica, fumed silica, precipitated silica, quartz, aluminum trihydrate, magnesium hydroxide, colemanite, titanium dioxide, snow white, fly ash, graphene nanoparticles, carbon black, recycled rubber tires, recycled shingles, recycled thermoplastic resins, basalt, roofing granules, clay, and combinations thereof. In other embodiments, non-limiting examples of NAS materials are disclosed in U.S. Patent Application Publication No. 2020/0224419 to Boss et al., which is incorporated by reference herein in its entirety.

In some embodiments, the first layer 30 is composed of fiberglass. In some embodiments, the first layer 30 is composed of a polymer with fiberglass. In some embodiments, the first layer 30 is composed of a synthetic roofing material. In some embodiments, the synthetic roofing material is a polyolefin coated, woven product. In some embodiments, the polyolefin coated, woven product comprises polypropylene.

In some embodiments, the first layer 30 has a thickness of 0.2 mm to 0.5 mm. In another embodiment, the first layer 30 has a thickness of 0.2 mm to 0.4 mm. In another embodiment, the first layer 30 has a thickness of 0.2 mm to 0.3 mm. In some embodiments, the first layer 30 has a thickness of 0.3 mm to 0.5 mm. In another embodiment, the first layer 30 has a thickness of 0.3 mm to 0.4 mm. In some embodiments, the first layer 30 has a thickness of 0.4 mm to 0.5 mm. In some embodiments, the first layer 30 has a thickness of 0.2 mm. In some embodiments, the first layer 30 has a thickness of 0.3 mm. In some embodiments, the first layer 30 has a thickness of 0.4 mm. In some embodiments, the first layer 30 has a thickness of 0.5 mm.

In some embodiments, the second layer 32 of the backsheet 28 is composed of one or more of the materials described above with respect to the first layer 30 of the backsheet 28. In some embodiments, the second layer 32 is composed of the same material as the first layer 30. In some embodiments, the second layer 32 is composed of substantially the same material as the first layer 30. In some embodiments, the second layer 32 is composed of a different material than that of the first layer 30.

In some embodiments, the second layer 32 has a thickness of 1 mm to 5 mm. In some embodiments, the second layer 32 has a thickness of 1 mm to 4 mm. In some embodiments, the second layer 32 has a thickness of 1 mm to 3 mm. In some embodiments, the second layer 32 has a thickness of 1 mm to 2 mm. In some embodiments, the second layer 32 has a thickness of 2 mm to 5 mm. In some embodiments, the second layer 32 has a thickness of 2 mm to 4 mm. In some embodiments, the second layer 32 has a thickness of 2 mm to 3 mm. In some embodiments, the second layer 32 has a thickness of 3 mm to 5 mm. In some embodiments, the second layer 32 has a thickness of 3 mm to 4 mm. In some embodiments, the second layer 32 has a thickness of 4 mm to 5 mm. In some embodiments, the second layer 32 has a thickness of 1 mm. In some embodiments, the second layer 32 has a thickness of 2 mm. In some embodiments, the second layer 32 has a thickness of 3 mm. In some embodiments, the second layer 32 has a thickness of 4 mm. In some embodiments, the second layer 32 has a thickness of 5 mm.

In some embodiments, the first layer 30 is attached to the second layer 32 by a second adhesive layer 34. In some embodiments, the second adhesive layer 34 may include polyvinyl butyrate, acrylic, silicone, or polycarbonate. In another embodiment, the second adhesive layer 34 may include pressure sensitive adhesives.

In some embodiments, the second adhesive layer 34 is composed of thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

In some embodiments, the second adhesive layer 34 has a thickness of 0.2 mm to 2 mm. In some embodiments, the second adhesive layer 34 has a thickness of 0.2 mm to 1.5 mm. In some embodiments, the second adhesive layer 34 has a thickness of 0.2 mm to 1 mm. In some embodiments, the second adhesive layer 34 has a thickness of 0.2 mm to 0.5 mm. In some embodiments, the second adhesive layer 34 has a thickness of 0.5 mm to 2 mm. In some embodiments, the second adhesive layer 34 has a thickness of 0.5 mm to 1.5 mm. In some embodiments, the second adhesive layer 34 has a thickness of 0.5 mm to 1 mm. In some embodiments, the second adhesive layer 34 has a thickness of 1 mm to 2 mm. In some embodiments, the second adhesive layer 34 has a thickness of 1 mm to 1.5 mm. In some embodiments, the second adhesive layer 34 has a thickness of 1.5 mm to 2 mm.

In some embodiments, the second adhesive layer 34 has a thickness of 0.2 mm. In some embodiments, the second adhesive layer 34 has a thickness of 0.3 mm. In some embodiments, the second adhesive layer 34 has a thickness of 0.4 mm. In some embodiments, the second adhesive layer 34 has a thickness of 0.45 mm. In some embodiments, the second adhesive layer 34 has a thickness of 0.5 mm. In some embodiments, the second adhesive layer 34 has a thickness of 1 mm. In some embodiments, the second adhesive layer 34 has a thickness of 1.5 mm. In some embodiments, the second adhesive layer 34 has a thickness of 2 mm. In some embodiments, the second adhesive layer 34 has a thickness of 2.5 mm. In some embodiments, the second adhesive layer 34 has a thickness of 3 mm. In some embodiments, the second adhesive layer 34 has a thickness of 3.5 mm. In some embodiments, the second adhesive layer 34 has a thickness of 4 mm.

In another embodiment, the second adhesive layer 34 has a thickness of 1 μm to 900 μm. In some embodiments, the second adhesive layer 34 has a thickness of 1 μm to 900 μm. In some embodiments, the second adhesive layer 34 has a thickness of 1 μm to 850 μm. In some embodiments, the second adhesive layer 34 has a thickness of 1 μm to 800 μm. In some embodiments, the second adhesive layer 34 has a thickness of 1 μm to 750 μm. In some embodiments, the second adhesive layer 34 has a thickness of 1 μm to 700 μm. In some embodiments, the second adhesive layer 34 has a thickness of 1 μm to 650 μm. In some embodiments, the second adhesive layer 34 has a thickness of 1 μm to 600 μm. In some embodiments, the second adhesive layer 34 has a thickness of 1 μm to 550 μm. In some embodiments, the second adhesive layer 34 has a thickness of 1 μm to 500 μm. In some embodiments, the second adhesive layer 34 has a thickness of 1 μm to 450 μm. In some embodiments, the second adhesive layer 34 has a thickness of 1 μm to 400 μm. In some embodiments, the second adhesive layer 34 has a thickness of 1 μm to 350 μm. In some embodiments, the second adhesive layer 34 has a thickness of 1 μm to 300 μm. In some embodiments, the second adhesive layer 34 has a thickness of 1 μm to 250 μm. In some embodiments, the second adhesive layer 34 has a thickness of 1 μm to 200 μm. In some embodiments, the second adhesive layer 34 has a thickness of 1 μm to 150 μm. In some embodiments, the second adhesive layer 34 has a thickness of 1 μm to 100 μm. In some embodiments, the second adhesive layer 34 has a thickness of 1 μm to 50 μm.

In some embodiments, the second adhesive layer 34 has a thickness of 50 μm to 900 μm. In some embodiments, the second adhesive layer 34 has a thickness of 50 μm to 850 μm. In some embodiments, the second adhesive layer 34 has a thickness of 50 μm to 800 μm. In some embodiments, the second adhesive layer 34 has a thickness of 50 μm to 750 μm. In some embodiments, the second adhesive layer 34 has a thickness of 50 μm to 700 μm. In some embodiments, the second adhesive layer 34 has a thickness of 50 μm to 650 μm. In some embodiments, the second adhesive layer 34 has a thickness of 50 μm to 600 μm. In some embodiments, the second adhesive layer 34 has a thickness of 50 μm to 550 μm. In some embodiments, the second adhesive layer 34 has a thickness of 50 μm to 500 μm. In some embodiments, the second adhesive layer 34 has a thickness of 50 μm to 450 μm. In some embodiments, the second adhesive layer 34 has a thickness of 50 μm to 400 μm. In some embodiments, the second adhesive layer 34 has a thickness of 50 μm to 350 μm. In some embodiments, the second adhesive layer 34 has a thickness of 50 μm to 300 μm. In some embodiments, the second adhesive layer 34 has a thickness of 50 μm to 250 μm. In some embodiments, the second adhesive layer 34 has a thickness of 50 μm to 200 μm. In some embodiments, the second adhesive layer 34 has a thickness of 50 μm to 150 μm. In some embodiments, the second adhesive layer 34 has a thickness of 50 μm to 100 μm.

In some embodiments, the second adhesive layer 34 has a thickness of 100 μm to 900 μm. In some embodiments, the second adhesive layer 34 has a thickness of 100 μm to 850 μm. In some embodiments, the second adhesive layer 34 has a thickness of 100 μm to 800 μm. In some embodiments, the second adhesive layer 34 has a thickness of 100 μm to 750 μm. In some embodiments, the second adhesive layer 34 has a thickness of 100 μm to 700 μm. In some embodiments, the second adhesive layer 34 has a thickness of 100 μm to 650 μm. In some embodiments, the second adhesive layer 34 has a thickness of 100 μm to 600 μm. In some embodiments, the second adhesive layer 34 has a thickness of 100 μm to 550 μm. In some embodiments, the second adhesive layer 34 has a thickness of 100 μm to 500 μm. In some embodiments, the second adhesive layer 34 has a thickness of 100 μm to 450 μm. In some embodiments, the second adhesive layer 34 has a thickness of 100 μm to 400 μm. In some embodiments, the second adhesive layer 34 has a thickness of 100 μm to 350 μm. In some embodiments, the second adhesive layer 34 has a thickness of 100 μm to 300 μm. In some embodiments, the second adhesive layer 34 has a thickness of 100 μm to 250 μm. In some embodiments, the second adhesive layer 34 has a thickness of 100 μm to 200 μm. In some embodiments, the second adhesive layer 34 has a thickness of 100 μm to 150 μm.

In some embodiments, the second adhesive layer 34 has a thickness of 150 μm to 900 μm. In some embodiments, the second adhesive layer 34 has a thickness of 150 μm to 850 μm. In some embodiments, the second adhesive layer 34 has a thickness of 150 μm to 800 μm. In some embodiments, the second adhesive layer 34 has a thickness of 150 μm to 750 μm. In some embodiments, the second adhesive layer 34 has a thickness of 150 μm to 700 μm. In some embodiments, the second adhesive layer 34 has a thickness of 150 μm to 650 μm. In some embodiments, the second adhesive layer 34 has a thickness of 150 μm to 600 μm. In some embodiments, the second adhesive layer 34 has a thickness of 150 μm to 550 μm. In some embodiments, the second adhesive layer 34 has a thickness of 150 μm to 500 μm. In some embodiments, the second adhesive layer 34 has a thickness of 150 μm to 450 μm. In some embodiments, the second adhesive layer 34 has a thickness of 150 μm to 400 μm. In some embodiments, the second adhesive layer 34 has a thickness of 150 μm to 350 μm. In some embodiments, the second adhesive layer 34 has a thickness of 150 μm to 300 μm. In some embodiments, the second adhesive layer 34 has a thickness of 150 μm to 250 μm. In some embodiments, the second adhesive layer 34 has a thickness of 150 μm to 200 μm.

In some embodiments, the second adhesive layer 34 has a thickness of 200 μm to 900 μm. In some embodiments, the second adhesive layer 34 has a thickness of 200 μm to 850 μm. In some embodiments, the second adhesive layer 34 has a thickness of 200 μm to 800 μm. In some embodiments, the second adhesive layer 34 has a thickness of 200 μm to 750 μm. In some embodiments, the second adhesive layer 34 has a thickness of 200 μm to 700 μm. In some embodiments, the second adhesive layer 34 has a thickness of 200 μm to 650 μm. In some embodiments, the second adhesive layer 34 has a thickness of 200 μm to 600 μm. In some embodiments, the second adhesive layer 34 has a thickness of 200 μm to 550 μm. In some embodiments, the second adhesive layer 34 has a thickness of 200 μm to 500 μm. In some embodiments, the second adhesive layer 34 has a thickness of 200 μm to 450 μm. In some embodiments, the second adhesive layer 34 has a thickness of 200 μm to 400 μm. In some embodiments, the second adhesive layer 34 has a thickness of 200 μm to 350 μm. In some embodiments, the second adhesive layer 34 has a thickness of 200 μm to 300 μm. In some embodiments, the second adhesive layer 34 has a thickness of 200 μm to 250 μm.

In some embodiments, the second adhesive layer 34 has a thickness of 250 μm to 900 μm. In some embodiments, the second adhesive layer 34 has a thickness of 250 μm to 850 μm. In some embodiments, the second adhesive layer 34 has a thickness of 250 μm to 800 μm. In some embodiments, the second adhesive layer 34 has a thickness of 250 μm to 750 μm. In some embodiments, the second adhesive layer 34 has a thickness of 250 μm to 700 μm. In some embodiments, the second adhesive layer 34 has a thickness of 250 μm to 650 μm. In some embodiments, the second adhesive layer 34 has a thickness of 250 μm to 600 μm. In some embodiments, the second adhesive layer 34 has a thickness of 250 μm to 550 μm. In some embodiments, the second adhesive layer 34 has a thickness of 250 μm to 500 μm. In some embodiments, the second adhesive layer 34 has a thickness of 250 μm to 450 μm. In some embodiments, the second adhesive layer 34 has a thickness of 250 μm to 400 μm. In some embodiments, the second adhesive layer 34 has a thickness of 250 μm to 350 μm. In some embodiments, the second adhesive layer 34 has a thickness of 250 μm to 300 μm. In some embodiments, the second adhesive layer 34 has a thickness of 300 μm to 900 μm. In some embodiments, the second adhesive layer 34 has a thickness of 300 μm to 850 μm. In some embodiments, the second adhesive layer 34 has a thickness of 300 μm to 800 μm. In some embodiments, the second adhesive layer 34 has a thickness of 300 μm to 750 μm. In some embodiments, the second adhesive layer 34 has a thickness of 300 μm to 700 μm. In some embodiments, the second adhesive layer 34 has a thickness of 300 μm to 650 μm. In some embodiments, the second adhesive layer 34 has a thickness of 300 μm to 600 μm. In some embodiments, the second adhesive layer 34 has a thickness of 300 μm to 550 μm. In some embodiments, the second adhesive layer 34 has a thickness of 300 μm to 500 μm. In some embodiments, the second adhesive layer 34 has a thickness of 300 μm to 450 μm. In some embodiments, the second adhesive layer 34 has a thickness of 300 μm to 400 μm. In some embodiments, the second adhesive layer 34 has a thickness of 300 μm to 350 μm.

In some embodiments, the second adhesive layer 34 has a thickness of 350 μm to 900 μm. In some embodiments, the second adhesive layer 34 has a thickness of 350 μm to 850 μm. In some embodiments, the second adhesive layer 34 has a thickness of 350 μm to 800 μm. In some embodiments, the second adhesive layer 34 has a thickness of 350 μm to 750 μm. In some embodiments, the second adhesive layer 34 has a thickness of 350 μm to 700 μm. In some embodiments, the second adhesive layer 34 has a thickness of 350 μm to 650 μm. In some embodiments, the second adhesive layer 34 has a thickness of 350 μm to 600 μm. In some embodiments, the second adhesive layer 34 has a thickness of 350 μm to 550 μm. In some embodiments, the second adhesive layer 34 has a thickness of 350 μm to 500 μm. In some embodiments, the second adhesive layer 34 has a thickness of 350 μm to 450 μm. In some embodiments, the second adhesive layer 34 has a thickness of 350 μm to 400 μm.

In some embodiments, the second adhesive layer 34 has a thickness of 400 μm to 900 μm. In some embodiments, the second adhesive layer 34 has a thickness of 400 μm to 850 μm. In some embodiments, the second adhesive layer 34 has a thickness of 400 μm to 800 μm. In some embodiments, the second adhesive layer 34 has a thickness of 400 μm to 750 μm. In some embodiments, the second adhesive layer 34 has a thickness of 400 μm to 700 μm. In some embodiments, the second adhesive layer 34 has a thickness of 400 μm to 650 μm. In some embodiments, the second adhesive layer 34 has a thickness of 400 μm to 600 μm. In some embodiments, the second adhesive layer 34 has a thickness of 400 μm to 550 μm. In some embodiments, the second adhesive layer 34 has a thickness of 400 μm to 500 μm. In some embodiments, the second adhesive layer 34 has a thickness of 400 μm to 450 μm.

In some embodiments, the second adhesive layer 34 has a thickness of 450 μm to 900 μm. In some embodiments, the second adhesive layer 34 has a thickness of 450 μm to 850 μm. In some embodiments, the second adhesive layer 34 has a thickness of 450 μm to 800 μm. In some embodiments, the second adhesive layer 34 has a thickness of 450 μm to 750 μm. In some embodiments, the second adhesive layer 34 has a thickness of 450 μm to 700 μm. In some embodiments, the second adhesive layer 34 has a thickness of 450 μm to 650 μm. In some embodiments, the second adhesive layer 34 has a thickness of 450 μm to 600 μm. In some embodiments, the second adhesive layer 34 has a thickness of 450 μm to 550 μm. In some embodiments, the second adhesive layer 34 has a thickness of 450 μm to 500 μm.

In some embodiments, the second adhesive layer 34 has a thickness of 500 μm to 900 μm. In some embodiments, the second adhesive layer 34 has a thickness of 500 μm to 850 μm. In some embodiments, the second adhesive layer 34 has a thickness of 500 μm to 800 μm. In some embodiments, the second adhesive layer 34 has a thickness of 500 μm to 750 μm. In some embodiments, the second adhesive layer 34 has a thickness of 500 μm to 700 μm. In some embodiments, the second adhesive layer 34 has a thickness of 500 μm to 650 μm. In some embodiments, the second adhesive layer 34 has a thickness of 500 μm to 600 μm. In some embodiments, the second adhesive layer 34 has a thickness of 500 μm to 550 μm.

In some embodiments, the second adhesive layer 34 has a thickness of 550 μm to 900 μm. In some embodiments, the second adhesive layer 34 has a thickness of 550 μm to 850 μm. In some embodiments, the second adhesive layer 34 has a thickness of 550 μm to 800 μm. In some embodiments, the second adhesive layer 34 has a thickness of 550 μm to 750 μm. In some embodiments, the second adhesive layer 34 has a thickness of 550 μm to 700 μm. In some embodiments, the second adhesive layer 34 has a thickness of 550 μm to 650 μm. In some embodiments, the second adhesive layer 34 has a thickness of 550 μm to 600 μm.

In some embodiments, the second adhesive layer 34 has a thickness of 600 μm to 900 μm. In some embodiments, the second adhesive layer 34 has a thickness of 600 μm to 850 μm. In some embodiments, the second adhesive layer 34 has a thickness of 600 μm to 800 μm. In some embodiments, the second adhesive layer 34 has a thickness of 600 μm to 750 μm. In some embodiments, the second adhesive layer 34 has a thickness of 600 μm to 700 μm. In some embodiments, the second adhesive layer 34 has a thickness of 600 μm to 650 μm.

In some embodiments, the second adhesive layer 34 has a thickness of 650 μm to 900 μm. In some embodiments, the second adhesive layer 34 has a thickness of 650 μm to 850 μm. In some embodiments, the second adhesive layer 34 has a thickness of 650 μm to 800 μm. In some embodiments, the second adhesive layer 34 has a thickness of 650 μm to 750 μm. In some embodiments, the second adhesive layer 34 has a thickness of 650 μm to 700 μm. In some embodiments, the second adhesive layer 34 has a thickness of 700 μm to 900 μm. In some embodiments, the second adhesive layer 34 has a thickness of 700 μm to 850 μm. In some embodiments, the second adhesive layer 34 has a thickness of 700 μm to 800 μm. In some embodiments, the second adhesive layer 34 has a thickness of 700 μm to 750 μm. In some embodiments, the second adhesive layer 34 has a thickness of 750 μm to 900 μm. In some embodiments, the second adhesive layer 34 has a thickness of 750 μm to 850 μm. In some embodiments, the second adhesive layer 34 has a thickness of 750 μm to 800 μm. In some embodiments, the second adhesive layer 34 has a thickness of 800 μm to 900 μm. In some embodiments, the second adhesive layer 34 has a thickness of 800 μm to 850 μm. In some embodiments, the second adhesive layer 34 has a thickness of 850 μm to 900 μm.

In some embodiments, the second adhesive layer 34 has a thickness of 1 μm. In some embodiments, the second adhesive layer 34 has a thickness of 50 μm. In some embodiments, the second adhesive layer 34 has a thickness of 100 μm. In some embodiments, the second adhesive layer 34 has a thickness of 1 μm. In some embodiments, the second adhesive layer 34 has a thickness of 150 μm. In some embodiments, the second adhesive layer 34 has a thickness of 200 μm. In some embodiments, the second adhesive layer 34 has a thickness of 250 μm. In some embodiments, the second adhesive layer 34 has a thickness of 300 μm. In some embodiments, the second adhesive layer 34 has a thickness of 350 μm. In some embodiments, the second adhesive layer 34 has a thickness of 400 μm. In some embodiments, the second adhesive layer 34 has a thickness of 450 μm. In some embodiments, the second adhesive layer 34 has a thickness of 500 μm. In some embodiments, the second adhesive layer 34 has a thickness of 550 μm. In some embodiments, the second adhesive layer 34 has a thickness of 600 μm. In some embodiments, the second adhesive layer 34 has a thickness of 650 μm. In some embodiments, the second adhesive layer 34 has a thickness of 700 μm. In some embodiments, the second adhesive layer 34 has a thickness of 750 μm. In some embodiments, the second adhesive layer 34 has a thickness of 800 μm. In some embodiments, the second adhesive layer 34 has a thickness of 850 μm. In some embodiments, the second adhesive layer 34 has a thickness of 900 μm.

In another embodiment, the first layer 30 is attached to the second layer 32 by thermal bonding.

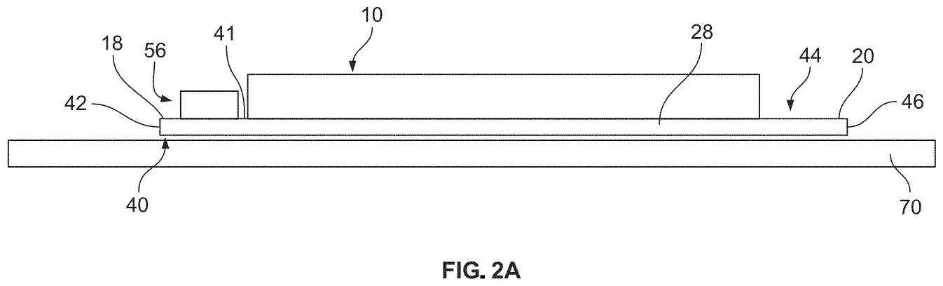

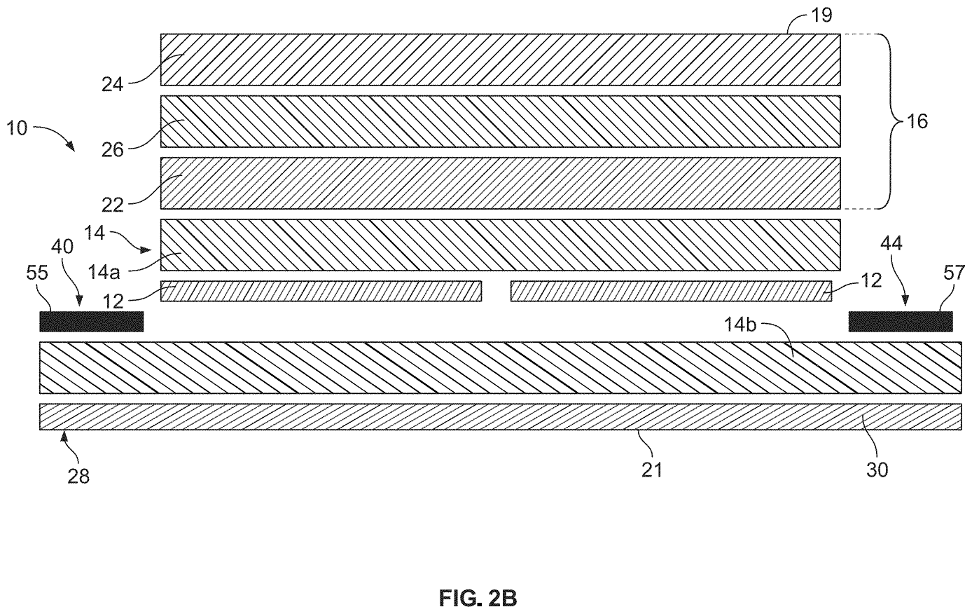

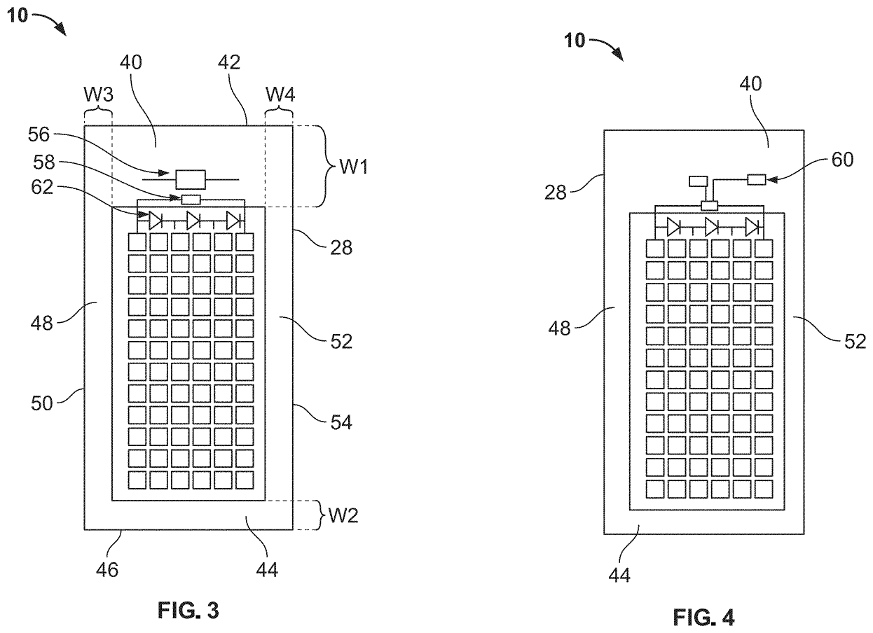

Referring to FIGS. 2A through 4, in some embodiments, the backsheet 28 includes a head flap 40. In some embodiments, the head flap 40 is located at a first end 42 of the photovoltaic module 10. In some embodiments, the backsheet 28 includes a bottom flap 44 located at a second end 46 of the photovoltaic module 10. In some embodiments, the bottom flap 44 is located opposite the head flap 40. In some embodiments, the backsheet 28 includes a first side flap 48. In some embodiments, the first side flap 48 is located at a first side 50 of the photovoltaic module 10. In some embodiments, the first side flap 48 extends from the first end 42 to the second end 46. In some embodiments, the first side flap 48 extends from the head flap 40 to the bottom flap 44. In some embodiments, the backsheet 28 includes a second side flap 52. In some embodiments, the second side flap 52 is located at a second side 54 of the photovoltaic module 10. In some embodiments, the second side flap 52 extends from the first end 42 to the second end 46. In some embodiments, the second side flap 52 extends from the head flap 40 to the bottom flap 44. In some embodiments, the head flap 40, the bottom flap 44, the first side flap 48 and the second side flap 52 are unitary with the backsheet 28.

Referring to FIG. 2B, in some embodiments, the head flap 40 includes a polymer layer 55. In some embodiments, the polymer layer 55 is juxtaposed with the second layer 14b of the encapsulant 14. In some embodiments, the bottom flap 44 includes a polymer layer 57. In some embodiments, the polymer layer 57 is juxtaposed with the second layer 14b of the encapsulant 14. In some embodiments, each of the polymer layers 55, 57 is composed of a polymeric material. In some embodiments, each of the polymer layers 55, 57 is composed of polyethylene terephthalate (“PET”). In some embodiments, each of the polymer layers 55, 57 is composed of ethylene tetrafluoroethylene (“ETFE”). In some embodiments, each of the polymer layers 55, 57 is composed of an acrylic such as polymethyl methacrylate (“PMMA”). In some embodiments, each of the polymer layers 55, 57 is composed of thermoplastic polyolefin (TPO). In some embodiments, each of the polymer layers 55, 57 is composed of polyvinyl chloride. In some embodiments, each of the polymer layers 55, 57 is composed of ethylene propylene diene monomer (EPDM) rubber. In some embodiments, each of the polymer layers 55, 57 is composed of HZF aramid reinforced polyamide.

In some embodiments, the polymer layer 55 has a thickness of 0.2 mm to 0.5 mm. In another embodiment, the polymer layer 55 has a thickness of 0.2 mm to 0.4 mm. In another embodiment, the polymer layer 55 has a thickness of 0.2 mm to 0.3 mm. In some embodiments, the polymer layer 55 has a thickness of 0.3 mm to 0.5 mm. In another embodiment, the polymer layer 55 has a thickness of 0.3 mm to 0.4 mm. In some embodiments, the polymer layer 55 has a thickness of 0.4 mm to 0.5 mm. In some embodiments, the polymer layer 55 has a thickness of 0.2 mm. In some embodiments, the polymer layer 55 has a thickness of 0.3 mm. In some embodiments, the polymer layer 55 has a thickness of 0.4 mm. In some embodiments, the polymer layer 55 has a thickness of 0.5 mm.

In some embodiments, the polymer layer 57 has a thickness of 0.2 mm to 0.5 mm. In another embodiment, the polymer layer 57 has a thickness of 0.2 mm to 0.4 mm. In another embodiment, the polymer layer 57 has a thickness of 0.2 mm to 0.3 mm. In some embodiments, the polymer layer 57 has a thickness of 0.3 mm to 0.5 mm. In another embodiment, the polymer layer 57 has a thickness of 0.3 mm to 0.4 mm. In some embodiments, the polymer layer 57 has a thickness of 0.4 mm to 0.5 mm. In some embodiments, the polymer layer 57 has a thickness of 0.2 mm. In some embodiments, the polymer layer 57 has a thickness of 0.3 mm. In some embodiments, the polymer layer 57 has a thickness of 0.4 mm. In some embodiments, the polymer layer 57 has a thickness of 0.5 mm.

In some embodiments, the photovoltaic module 10 is configured to be attached to a roofing membrane 70 of a roof deck. In some embodiments, the roof deck is a component of a commercial roof. In some embodiments, the roof deck is a component of a residential roof.

In some embodiments, the roof deck is a flat roof deck—that is, the roof deck has zero slope. In some embodiments, the roof deck has a slope of 3 inches per foot or less. In some embodiments, the roof deck has a slope of 0.25 inch to 3 inches per foot. In some embodiments, the roof deck has a slope of 0.25 inch to 2 inches per foot. In some embodiments, the roof deck has a slope of 0.25 inch to 1 inch per foot. In some embodiments, the roof deck has a slope of 1 inch to 3 inches per foot. In some embodiments, the roof deck has a slope of 1 inch to 2 inches per foot. In some embodiments, the roof deck has a slope of 2 inches to 3 inches per foot.

In some embodiments, the roof deck is a steep slope roof deck. As defined herein, a “steep slope roof deck” is any roof deck that is disposed on a roof having a pitch of Y/X, where Y and X are in a ratio of 4:12 to 12:12, where Y corresponds to the “rise” of the roof, and where X corresponds to the “run” of the roof.

In some embodiments, the roof deck is sloped (that is, the roof deck is not flat), but the roof deck has a slope less than that of a steep slope roof deck.

In some embodiments, the roofing membrane 70 is a preexisting roofing membrane installed on the roof deck. In some embodiments, an upper, outermost surface of the roofing membrane 70 opposite the roof deck is cleaned by a cleaning process.

In some embodiments, the head flap 40 is attached to the roofing membrane 70. In some embodiments, the bottom flap 44 is attached to the roofing membrane 70. In some embodiments, the first side flap 48 is attached to the roofing membrane 70. In some embodiments, the second side flap 52 is attached to the roofing membrane 70. In some embodiments, each of the first side flap 48 and the second side flap 52 is configured to prevent wind uplift. In an embodiment, the roofing membrane 70 is made from a polymeric material. In some embodiments, the roofing membrane 70 is composed of polyethylene terephthalate (“PET”). In another embodiment, the roofing membrane 70 is composed of ethylene tetrafluoroethylene (“ETFE”). In some embodiments, the roofing membrane 70 is composed of an acrylic such as polymethyl methacrylate (“PMMA”). In some embodiments, the roofing membrane 70 is composed of thermoplastic polyolefin (TPO). In some embodiments, the roofing membrane 70 is composed of polyvinyl chloride. In some embodiments, the roofing membrane 70 is composed of ethylene propylene diene monomer (EPDM) rubber. In some embodiments, the photovoltaic module 10 is attached to the roofing membrane 70 by an adhesive. In some embodiments, the adhesive is a peel and stick film sheet. In some embodiments, the peel and stick film sheet includes at least one sheet of film removably attached to a rear, lower most surface of the photovoltaic module 10. In some embodiments, the peel and stick film sheet is composed of EverGuard Freedom HW peel and stick membrane manufactured by GAF. In some embodiments, the adhesive includes polyvinyl butyrate, acrylic, silicone, or polycarbonate. In some embodiments, the adhesive includes pressure sensitive adhesives. In some embodiments, the photovoltaic module 10 is attached to the roofing membrane 70 by thermal bonding. In some embodiments, the photovoltaic module 10 is attached to the roofing membrane 70 by ultrasonic welding. In some embodiments, the photovoltaic module 10 is attached to the roofing membrane 70 by heat welding. In some embodiments, the photovoltaic module 10 is attached to the roofing membrane 70 by induction welding. In some embodiments, the photovoltaic module 10 is attached to the roofing membrane 70 by hot air welding. In some embodiments, the photovoltaic module 10 is attached to the roofing membrane 70 by a mechanical crimping. In some embodiments, the photovoltaic module 10 is attached to the roofing membrane 70 by at least one fastener. In some embodiments, the at least one fastener includes a plurality of the fasteners. In some embodiments, the at least one fastener includes a nail. In some embodiments, the at least one fastener includes a screw. In some embodiments, the at least one fastener includes a rivet. In some embodiments, the at least one fastener includes a staple.

In some embodiments, the photovoltaic module 10 may be installed directly on the roof deck—that is, with no intervening member, membrane, component, composition, or additional layer, such as the roofing membrane 70, between the roof deck and the photovoltaic module 10. In some embodiments, the photovoltaic module 10 may be installed on the roof deck by any of the described ways of attaching the photovoltaic module 10 to another component, including by an adhesive, thermal bonding, ultrasonic welding, induction welding, hot air welding, mechanical crimping, and/or fasteners. In some other embodiments, the photovoltaic module 10 may be installed indirectly on the roofing deck, such that there is one or more intervening layers between the roof deck and the photovoltaic module 10.

In some embodiments, a width W1 of the head flap 40 is 1 inch to 50 inches. In some embodiments, the width W1 of the head flap 40 is 1 inch to 40 inches. In some embodiments, the width W1 of the head flap 40 is 1 inch to 30 inches. In some embodiments, the width W1 of the head flap 40 is 1 inch to 20 inches. In some embodiments, the width W1 of the head flap 40 is 1 inch to 10 inches. In some embodiments, the width W1 of the head flap 40 is 10 inches to 50 inches. In some embodiments, the width W1 of the head flap 40 is 10 inches to 40 inches. In some embodiments, the width W1 of the head flap 40 is 10 inches to 30 inches. In some embodiments, the width W1 of the head flap 40 is 10 inches to 20 inches. In some embodiments, the width W1 of the head flap 40 is 20 inches to 50 inches. In some embodiments, the width W1 of the head flap 40 is 20 inches to 40 inches. In some embodiments, the width W1 of the head flap 40 is 20 inches to 30 inches. In some embodiments, the width W1 of the head flap 40 is 30 inches to 50 inches. In some embodiments, the width W1 of the head flap 40 is 30 inches to 40 inches. In some embodiments, the width W1 of the head flap 40 is 40 inches to 50 inches. In some embodiments, the width W1 of the head flap 40 is 1 inch. In some embodiments, the width W1 of the head flap 40 is 10 inches. In some embodiments, the width W1 of the head flap 40 is 20 inches. In some embodiments, the width W1 of the head flap 40 is 30 inches. In some embodiments, the width W1 of the head flap 40 is 40 inches. In some embodiments, the width W1 of the head flap 40 is 50 inches.

In some embodiments, a width W2 of the bottom flap 44 is 1 inch to 50 inches. In some embodiments, the width W2 of the bottom flap 44 is 1 inch to 40 inches. In some embodiments, the width W2 of the bottom flap 44 is 1 inch to 30 inches. In some embodiments, the width W2 of the bottom flap 44 is 1 inch to 20 inches. In some embodiments, the width W2 of the bottom flap 44 is 1 inch to 10 inches. In some embodiments, the width W2 of the bottom flap 44 is 10 inches to 50 inches. In some embodiments, the width W2 of the bottom flap 44 is 10 inches to 40 inches. In some embodiments, the width W2 of the bottom flap 44 is 10 inches to 30 inches. In some embodiments, the width W2 of the bottom flap 44 is 10 inches to 20 inches. In some embodiments, the width W2 of the bottom flap 44 is 20 inches to 50 inches. In some embodiments, the width W2 of the bottom flap 44 is 20 inches to 40 inches. In some embodiments, the width W2 of the bottom flap 44 is 20 inches to 30 inches. In some embodiments, the width W2 of the bottom flap 44 is 30 inches to 50 inches. In some embodiments, the width W2 of the bottom flap 44 is 30 inches to 40 inches. In some embodiments, the width W2 of the bottom flap 44 is 40 inches to 50 inches. In some embodiments, the width W2 of the bottom flap 44 is 1 inch. In some embodiments, the width W2 of the bottom flap 44 is 10 inches. In some embodiments, the width W2 of the bottom flap 44 is 20 inches. In some embodiments, the width W2 of the bottom flap 44 is 30 inches. In some embodiments, the width W2 of the bottom flap 44 is 40 inches. In some embodiments, the width W2 of the bottom flap 44 is 50 inches.

In some embodiments, a width W3 of the first side flap 48 is 1 inch to 50 inches. In some embodiments, the width W3 of the first side flap 48 is 1 inch to 40 inches. In some embodiments, the width W3 of the first side flap 48 is 1 inch to 30 inches. In some embodiments, the width W3 of the first side flap 48 is 1 inch to 20 inches. In some embodiments, the width W3 of the first side flap 48 is 1 inch to 10 inches. In some embodiments, the width W3 of the first side flap 48 is 10 inches to 50 inches. In some embodiments, the width W3 of the first side flap 48 is 10 inches to 40 inches. In some embodiments, the width W3 of the first side flap 48 is 10 inches to 30 inches. In some embodiments, the width W3 of the first side flap 48 is 10 inches to 20 inches. In some embodiments, the width W3 of the first side flap 48 is 20 inches to 50 inches. In some embodiments, the width W3 of the first side flap 48 is 20 inches to 40 inches. In some embodiments, the width W3 of the first side flap 48 is 20 inches to 30 inches. In some embodiments, the width W3 of the first side flap 48 is 30 inches to 50 inches. In some embodiments, the width W3 of the first side flap 48 is 30 inches to 40 inches. In some embodiments, the width W3 of the first side flap 48 is 40 inches to 50 inches. In some embodiments, the width W3 of the first side flap 48 is 1 inch. In some embodiments, the width W3 of the first side flap 48 is 10 inches. In some embodiments, the width W3 of the first side flap 48 is 20 inches. In some embodiments, the width W3 of the first side flap 48 is 30 inches. In some embodiments, the width W3 of the first side flap 48 is 40 inches. In some embodiments, the width W3 of the first side flap 48 is 50 inches.

In some embodiments, a width W4 of the second side flap 52 is 1 inch to 50 inches. In some embodiments, the width W4 of the second side flap 52 is 1 inch to 40 inches. In some embodiments, the width W4 of the second side flap 52 is 1 inch to 30 inches. In some embodiments, the width W4 of the second side flap 52 is 1 inch to 20 inches. In some embodiments, the width W4 of the second side flap 52 is 1 inch to 10 inches. In some embodiments, the width W4 of the second side flap 52 is 10 inches to 50 inches. In some embodiments, the width W4 of the second side flap 52 is 10 inches to 40 inches. In some embodiments, the width W4 of the second side flap 52 is 10 inches to 30 inches. In some embodiments, the width W4 of the second side flap 52 is 10 inches to 20 inches. In some embodiments, the width W4 of the second side flap 52 is 20 inches to 50 inches. In some embodiments, the width W4 of the second side flap 52 is 20 inches to 40 inches. In some embodiments, the width W4 of the second side flap 52 is 20 inches to 30 inches. In some embodiments, the width W4 of the second side flap 52 is 30 inches to 50 inches. In some embodiments, the width W4 of the second side flap 52 is 30 inches to 40 inches. In some embodiments, the width W4 of the second side flap 52 is 40 inches to 50 inches. In some embodiments, the width W4 of the second side flap 52 is 1 inch. In some embodiments, the width W4 of the second side flap 52 is 10 inches. In some embodiments, the width W4 of the second side flap 52 is 20 inches. In some embodiments, the width W4 of the second side flap 52 is 30 inches. In some embodiments, the width W4 of the second side flap 52 is 40 inches. In some embodiments, the width W4 of the second side flap 52 is 50 inches.

In some embodiments, at least a portion of the head flap 40 is attached to the roofing membrane 70. In some embodiments, a width of 1 inch to 2 inches of the head flap 40 is attached to the roofing membrane 70. In some embodiments, at least a portion of the bottom flap 44 is attached to the roofing membrane 70. In some embodiments, a width of 1 inch to 2 inches of the bottom flap 44 is attached to the roofing membrane 70. In some embodiments, the first side flap 48 is attached to the roofing membrane 70. In some embodiments, a width of 1 inch to 2 inches of the first side flap 48 is attached to the roofing membrane 70. In some embodiments, the second side flap 52 is attached to the roofing membrane 70. In some embodiments, a width of 1 inch to 2 inches of the second side flap 52 is attached to the roofing membrane 70.

In some embodiments, the photovoltaic module 10 includes at least one junction box 56. In some embodiments, the at least one junction box 56 is located on a first surface 41 of the head flap 40. In some embodiments, the at least one junction box 56 is attached to the first surface 41 of the head flap 40. In some embodiments, the polymer layer 55 includes the first surface 41. In some embodiments, the at least one junction box 56 is laminated within the head flap 40. In some embodiments, the at least one junction box 56 is encapsulated within the encapsulant 14. In some embodiments, the photovoltaic module 10 includes at least one module level power electronic component 58. In some embodiments, the at least one module level power electronic component 58 is located on the first surface 41 of the head flap 40. In some embodiments, the at least one module level power electronic component 58 is attached to the first surface 41 of the head flap 40. In some embodiments, the at least one module level power electronic component 58 is laminated within the head flap 40. In some embodiments, the photovoltaic module 10 includes at least one electrical connector 60. In some embodiments, the photovoltaic module 10 includes at least one electrical connector 60. In some embodiments, the at least one electrical connector 60 is a low profile electrical connector. In some embodiments, the at least one electrical connector 60 has a thickness of 1 mm to 10 mm. In some embodiments, the at least one electrical connector 60 is a flat ribbon cable. In some embodiments, the at least one electrical connector 60 is attached to the first surface 41 of the head flap 40. In some embodiments, the at least one electrical connector 60 is laminated within the head flap 40. In some embodiments, the photovoltaic module 10 includes at least one diode 62. In some embodiments, the at least one diode 62 is laminated within the encapsulant 14.

In some embodiments, the photovoltaic module 10 is configured (e.g., sized, shaped, positioned, made using a suitable material, etc.) such that it passes the UL 7103 standard for walkability (e.g., a “200 pound roofer test”). This test involves attaching the photovoltaic module 10 to a representative model of a roof and setting a 200-pound weight on a 3-inch diameter puck on the photovoltaic module 10 for 30 minutes. A photovoltaic module is deemed to pass the UL 7103 standard if there are no penetrations at the end of the 30-minute time period.

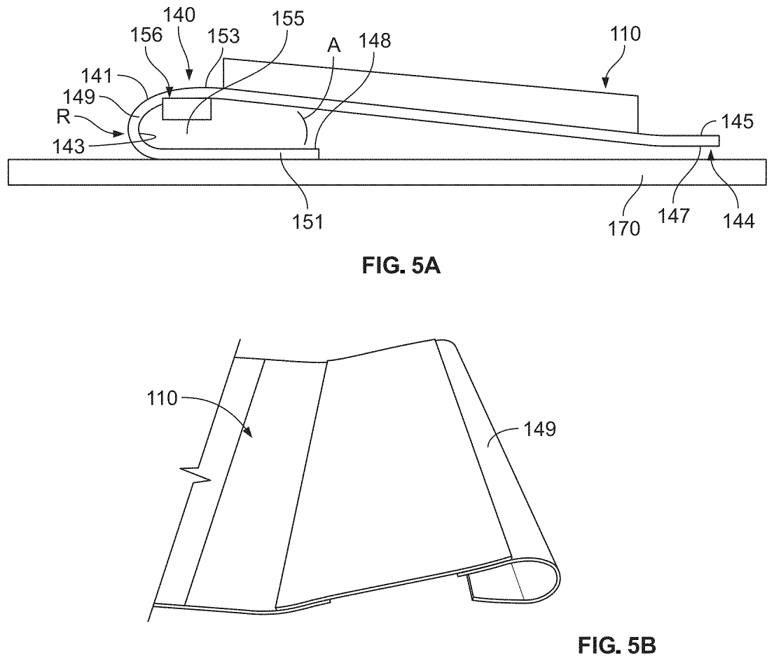

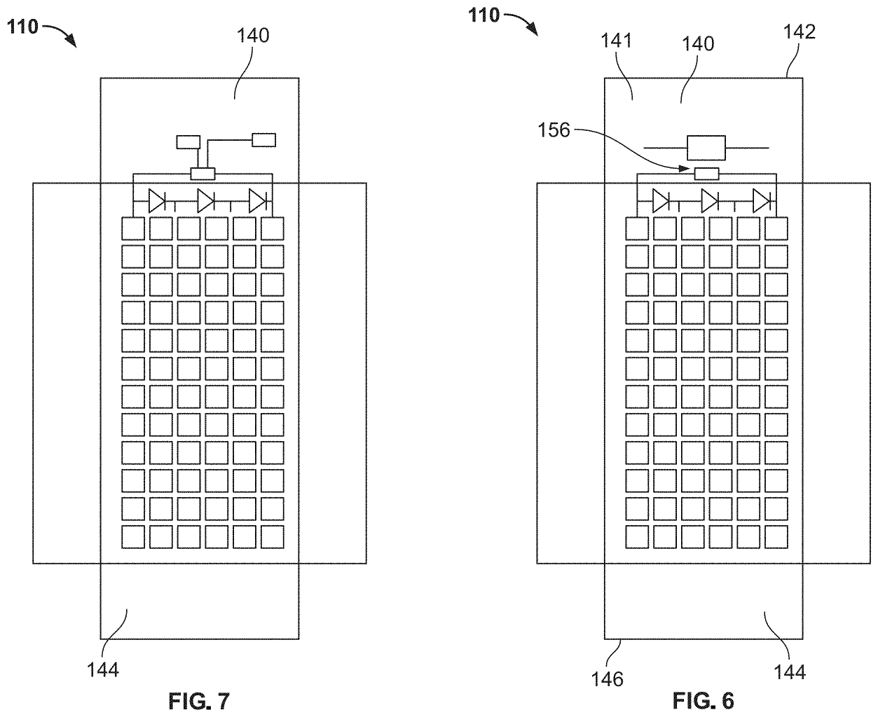

FIGS. 5A through 7 show an embodiment of a photovoltaic module 110. In some embodiments, the photovoltaic module 110 includes a structure and function similar to those of the photovoltaic module 10, except for certain differences provided herein. In some embodiments, the photovoltaic module 110 includes a head flap 140 located at a first end 142 of the photovoltaic module 110 and a bottom flap 144 located at a second end 146 of the photovoltaic module 110. In some embodiments, the head flap 140 incudes a first surface 141 and a second surface 143 opposite the first surface 141. In some embodiments, the bottom flap 144 includes a first surface 145 and a second surface 147 opposite the first surface 145.

In some embodiments, a free end 148 of the head flap 140 is bent and folded relative to itself such that it forms a rounded end 149. In some embodiments, the head flap 140 includes one fold. In some embodiments, the rounded end 149 includes a first portion 151 juxtaposed with the roofing membrane 170 and a second portion 153 that is distal from the roofing membrane 170. In some embodiments, the second portion 153 is elevated relative to the roofing membrane 170. In an embodiment, the first surface 141 of at least the first portion 151 is attached to the roofing membrane 170. In some embodiments, a second portion 153 of the rounded end 149 is elevated relative to the roofing membrane 170, such that the photovoltaic module 110 is sloped at an angle A relative to the roofing membrane 170. In some embodiments, the angle A is 0.1 degrees to 15 degrees. In some embodiments, the angle A is 0.1 degrees to 10 degrees. In some embodiments, the angle A is 0.1 degrees to 5 degrees. In some embodiments, the angle A is 5 degrees to 15 degrees. In some embodiments, the angle A is 5 degrees to 10 degrees. In some embodiments, the angle A is 10 degrees to 15 degrees. In some embodiments, the angle A is 5 degrees. In some embodiments, the angle A is 10 degrees. In some embodiments, the angle A is 15 degrees. In some embodiments, the angle A is 0.1 degree. In some embodiments, the angle A is 0 degrees. In some embodiments, at least a portion of the second surface 147 of the bottom flap 144 is attached to the roofing membrane 170. In some embodiments, the photovoltaic module 110 is configured to be a watershedding layer of the roofing system. In some embodiments, the slope of the photovoltaic module 110 prevents water pooling thereon. In some embodiments, the first surface 141 of the head flap 140 includes indicia representing markings of the locations to attach the head flap 140 to the roofing membrane 170 to obtain the corresponding angle A. In some embodiments, the rounded end 149 includes a radius of curvature R.

In some embodiments, a space 155 is formed between the first portion 151 of the rounded end 149 and the second portion 153 of the rounded end 149. In some embodiments, a junction box 156 is attached to the second surface 143 of the head flap 140. In some embodiments, the junction box 156 is attached to the first surface 141 of the head flap 140. In some embodiments, the junction box 156 is located within the space 155. In some embodiments, the second portion 153 is perforated. In some embodiments, the second portion 153 includes perforations that are configured to release air within the space 155, due to wind or otherwise, and prevent the first portion 151 from being detached from the roofing membrane 170. In some embodiments, the rounded end 149 is configured to be flexible and collapsible for walkability. In some embodiments, the space 155 is sized and shaped to enable the rounded end 149 to be collapsible.

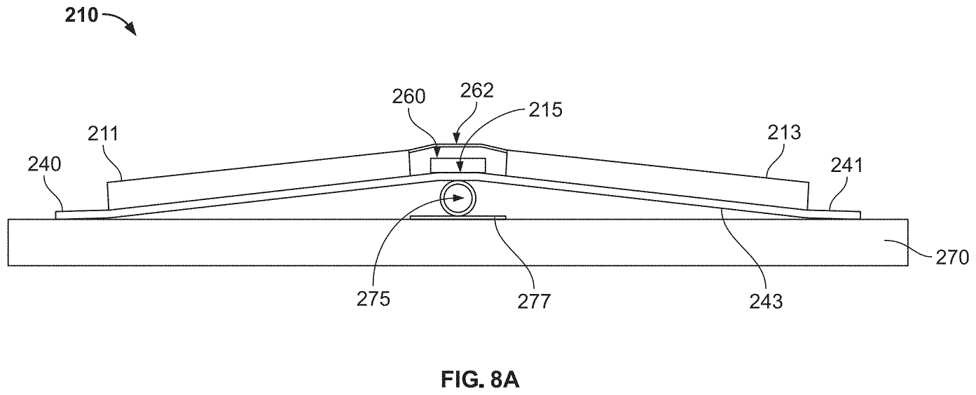

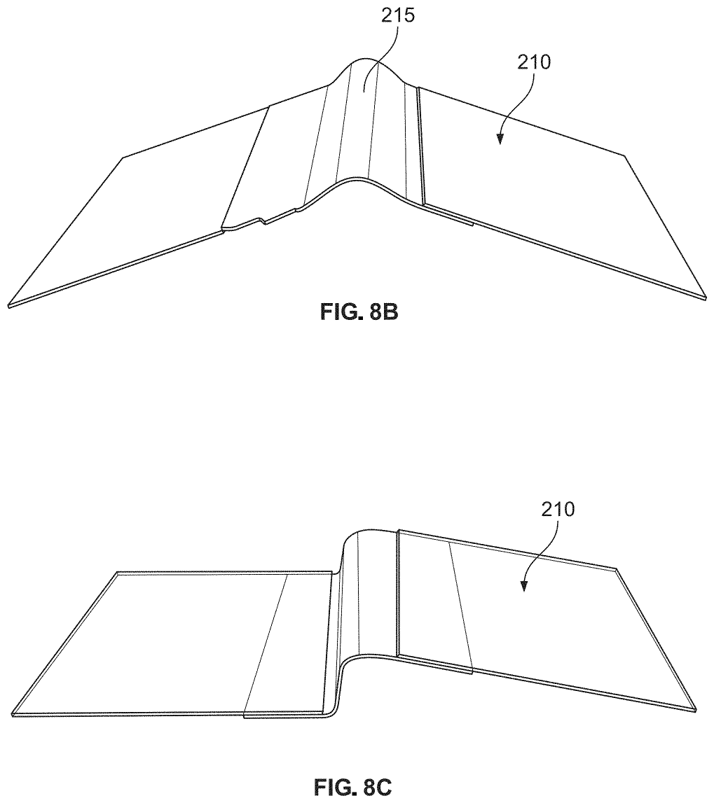

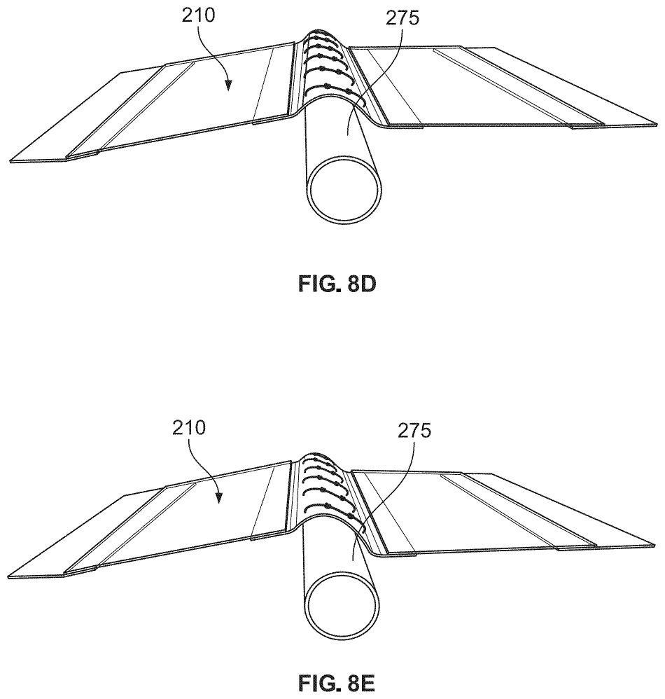

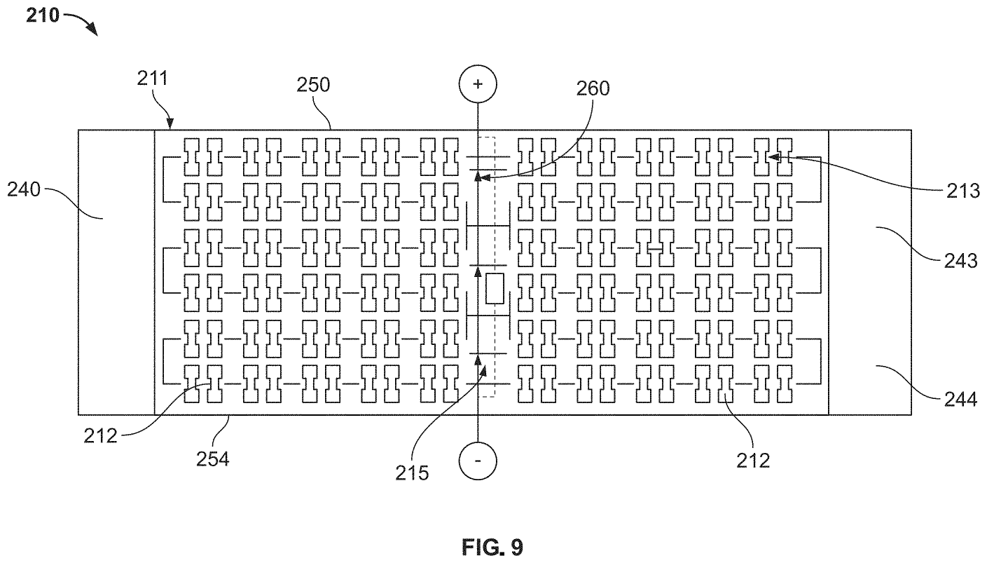

FIGS. 8A through 9 show an embodiment of a photovoltaic module 210. In some embodiments, the photovoltaic module 210 includes a structure and function similar to those of the photovoltaic module 10, except for certain differences provided herein. In some embodiments, the photovoltaic module 210 includes a first portion 211, a second portion 213, and a region 215 located intermediate the first portion 211 and the second portion 213. In some embodiment, the first portion 211 includes a first array of a plurality of solar cells 212 and the second portion 213 includes a second array of the plurality of solar cells 212. In some embodiments, the region 215 extends from a first side 250 of the photovoltaic module 210 to a second side 254 of the photovoltaic module 210 opposite the first side 250. In some embodiments, the region 215 is centrally-located. In some embodiments, the region 215 does not include any of the plurality of solar cells 212. In some embodiments, the region 215 includes a reinforcing layer. In some embodiments, at least one electrical component 260 is located on a first surface 241 of the photovoltaic module 210 and within the region 215. In some embodiments, at least one electrical component 260 is laminated within the photovoltaic module 210 and in the region 215. In some embodiments, the at least one electrical component 260 includes a junction box. In some embodiments, the at least one electrical component 260 includes a diode. In some embodiments, the at least one electrical component 260 includes a module level power electronic component. In some embodiments, the at least one electrical component 260 includes an optimizer. In some embodiments, the at least one electrical component 260 includes an electrical connector. In some embodiments, the photovoltaic module 210 includes a cover 262 that covers the at least one electrical component 260. In some embodiments, the cover 262 covers the region 215.

In some embodiments, the cover 262 is composed of polyvinyl chloride. In some embodiments, the cover 262 is flexible. In some embodiments, the cover 262 is elastic. In some embodiments, the cover 262 is rigid.

In some embodiments, the first portion 211 of the photovoltaic module 210 includes a head flap 240. In some embodiments, the head flap 240 is located proximate to the first array of the plurality of solar cells 212. In some embodiments, the second portion 213 of the photovoltaic module 210 includes a bottom flap 244. In some embodiments, the bottom flap 244 is located proximate to the second array of the plurality of solar cells 212.

In some embodiments, the photovoltaic module 210 is attached to a roofing membrane 270 of a roofing system. In some embodiments, at least a portion of the head flap 240 is attached to the roofing membrane 270. In some embodiments, at least a portion of the bottom flap 244 is attached to the roofing membrane 270. In some embodiments, a support member 275 is positioned intermediate the roofing membrane 270 and a second surface 243 of the photovoltaic module 210. In some embodiments, the support member 275 is located beneath the region 215. In some embodiments, the support member 275 includes a rod. In some embodiments, the support member 275 includes a tubular rod. In an embodiment, the tubular rod is configured to receive electrical wire. In some embodiments, the support member 275 includes a cylindrical-shaped cross-section. In some embodiments, the support member 275 is square-shaped cross-section. In some embodiments, the support member 275 is rectangular-shaped cross-section. In some embodiments, the support member 275 includes a triangular-shaped cross-section. In some embodiments, the support member 275 includes an elliptical-shaped cross-section. In some embodiments, the support member 275 includes a U-shaped cross-section. In some embodiments, the support member 275 includes a base 277. In some embodiments, the base 277 is flat. In some embodiments, the base 277 is attached to the roofing membrane 270.

In some embodiments, the support member 275 is composed of a polymeric material. In some embodiments, the support member 275 is composed of polyethylene terephthalate (“PET”). In some embodiments, the support member 275 is composed of ethylene tetrafluoroethylene (“ETFE”). In some embodiments, the support member 275 is composed of an acrylic such as polymethyl methacrylate (“PMMA”). In some embodiments, the support member 275 is composed of thermoplastic polyolefin (TPO). In some embodiments, the support member 275 is composed of polyvinyl chloride. In some embodiments, the support member 275 is composed of ethylene propylene diene monomer (EPDM) rubber. In some embodiments, the support member 275 is composed of metal. In some embodiments, the support member 275 is flexible. In some embodiments, the support member 275 is elastic. In some embodiments, the support member 275 is rigid.

In some embodiments, the support member 275 elevates at least a portion of the photovoltaic module 210 over the roofing membrane 270. In some embodiments, the support member 275 elevates the region 215 over the roofing membrane 270. In some embodiments, the support member 275 elevates at least a portion of the first portion 211 over the roofing membrane 270. In some embodiments, the support member 275 elevates at least a portion of the second portion 213 over the roofing membrane 270. In some embodiments, the first portion 211 is sloped at an angle A relative to the roofing membrane 270. In some embodiments, the angle A is 0.1 degrees to 15 degrees. In some embodiments, the angle A is 0.1 degrees to 10 degrees. In some embodiments, the angle A is 0.1 degrees to 5 degrees. In some embodiments, the angle A is 5 degrees to 15 degrees. In some embodiments, the angle A is 5 degrees to 10 degrees. In some embodiments, the angle A is 10 degrees to 15 degrees. In some embodiments, the angle A is 5 degrees. In some embodiments, the angle A is 10 degrees. In some embodiments, the angle A is 15 degrees.

In some embodiments, the second portion 213 is sloped at an angle B relative to the roofing membrane 270. In some embodiments, the angle B is 0.1 degrees to 15 degrees. In some embodiments, the angle B is 0.1 degrees to 10 degrees. In some embodiments, the angle B is 0.1 degrees to 5 degrees. In some embodiments, the angle B is 5 degrees to 15 degrees. In some embodiments, the angle B is 5 degrees to 10 degrees. In some embodiments, the angle B is 10 degrees to 15 degrees. In some embodiments, the angle B is 0.1 degree. In some embodiments, the angle B is 5 degrees. In some embodiments, the angle B is 10 degrees. In some embodiments, the angle B is 15 degrees. In some embodiments, the angle B is 0 degrees. In some embodiments, the angle A is equal to the angle B. In some embodiments, the angle A is substantially the same as the angle B. In some embodiments, the angle A is different from the angle B. In some embodiments, the slopes of the photovoltaic module 210 prevent water pooling thereon.

In some embodiments, the region 215 is configured to be flexible and stretchable. In some embodiments, the region 215 is configured to be flexed and stretched when the support member 275 is positioned intermediate the region 215 and the roofing membrane 270. In some embodiments, each of the first portion 211 and the second portion 213 is configured to be flexible and collapsible for walkability. Referring to FIGS. 8B through 8E, in some embodiments, the support member 275 is sized and shaped to enable the first portion 211 and the second portion 213 to be collapsible.

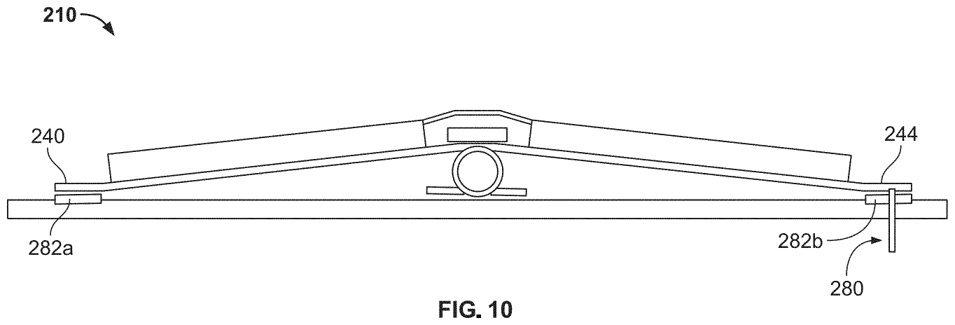

In some embodiments, each of the head flap 240 and the bottom flap 244 is attached to the roofing membrane 270 by an adhesive. In some embodiments, each of the head flap 240 and the bottom flap 244 is attached to the roofing membrane 270 by thermal bonding. In some embodiments, each of the head flap 240 and the bottom flap 244 is attached to the roofing membrane 270 by ultrasonic welding. Referring to FIG. 10, in some embodiments, each of the head flap 240 and the bottom flap 244 is attached to the roofing membrane 270 by at least one fastener 280. In some embodiments, the at least one fastener 280 includes a plurality of the fasteners 280. In some embodiments, the at least one fastener 280 includes a nail. In some embodiments, the at least one fastener 280 includes a screw. In some embodiments, the at least one fastener 280 includes a rivet. In some embodiments, lower flaps 282a, 282b are positioned intermediate the head flap 240 and the roofing membrane 270 and the bottom flap 244 and the roofing membrane 270, respectively.

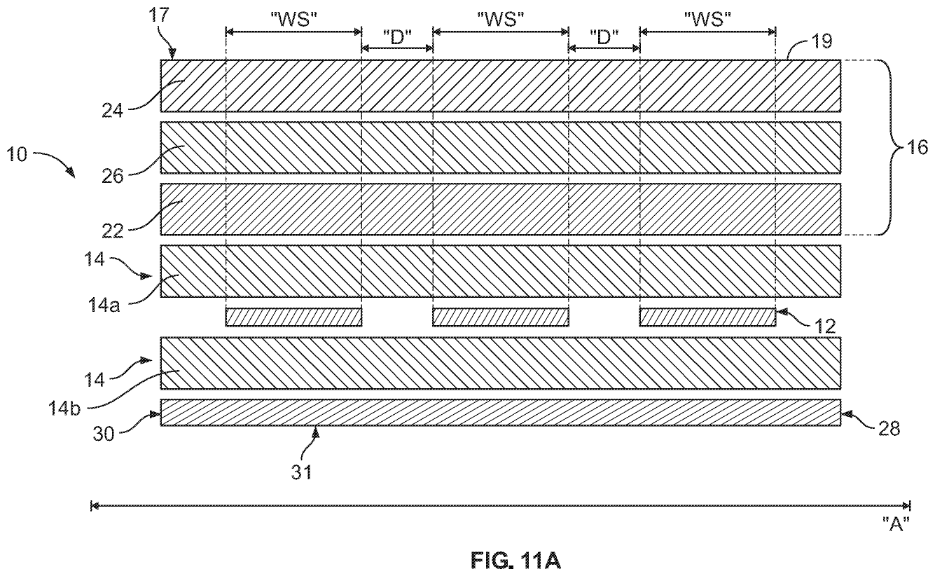

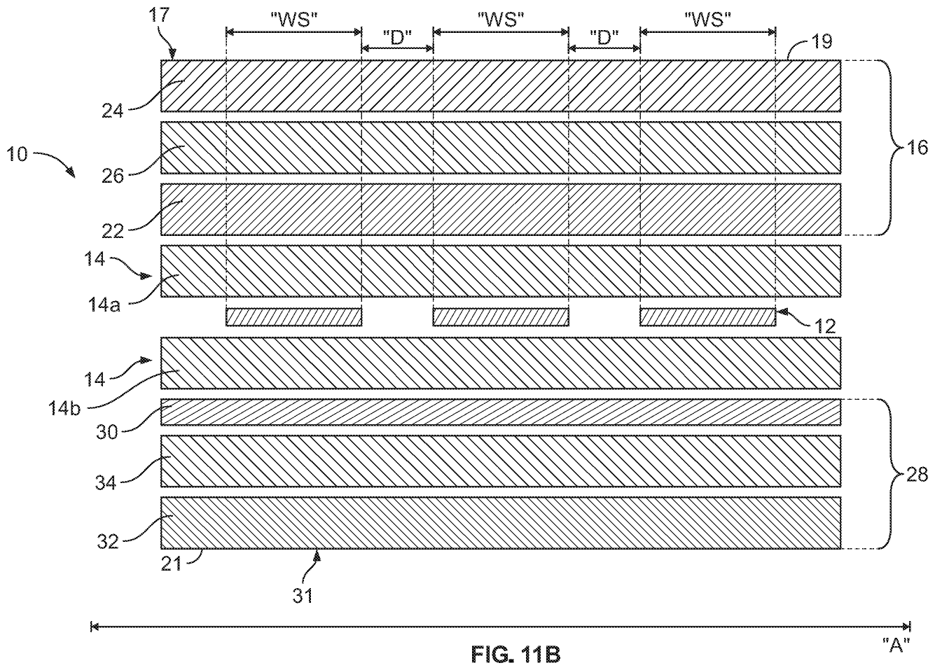

Referring to FIGS. 11A and 11B, in some embodiments, the photovoltaic module 10 includes a plurality of the solar cells 12, the encapsulant 14 encapsulating the solar cells 12, the frontsheet 16 juxtaposed with one surface of the encapsulant 14, and the backsheet 28 juxtaposed with another surface of the encapsulant 14. In some embodiments, the backsheet 28 includes a first layer 30. Any or all of the photovoltaic module 10, the solar cells 12, the encapsulant 14, the frontsheet 16, and/or the backsheet 28 may be as further described herein. As discussed, in some embodiments, the elements of the photovoltaic module 10 may be laminated with each other, such that the photovoltaic module 10 is in the form of a laminate.

In some embodiments, as shown in FIGS. 11A and 11B, the frontsheet 16 may include one or more, or all of, the glass layer 22 juxtaposed with the polymer layer 24, and the polymer layer 24 attached to the glass layer 22 by the first adhesive layer 26. Any or all of the glass layer 22, the polymer layer 24, and/or the first adhesive layer 26 may be as further described herein. In some embodiments, the frontsheet 16 may include the polymer layer 24, while omitting the glass layer 22 and the first adhesive layer 26.

In some embodiments, as shown in FIG. 11A, the photovoltaic module 10 may include the backsheet 28 having the first layer 30, and omitting other layers of the backsheet 28 described herein. However, in some embodiments, as shown in FIG. 11B, the backsheet 28 may include the first layer 30, the second layer 32, and the second adhesive layer 34 attaching the first layer 30 and the second layer 32. Any or all of the first layer 30, the second layer 32, and/or the second adhesive layer 34 may be as described herein. For example, as discussed, in some embodiments, one or more, or all of, the first layer 30, the second layer 32, and/or the second adhesive layer 34 may be composed of thermoplastic polyolefin (TPO). In some embodiments, the backsheet 28 may include the first layer 30, while omitting the second layer 32 and the second adhesive layer 34.

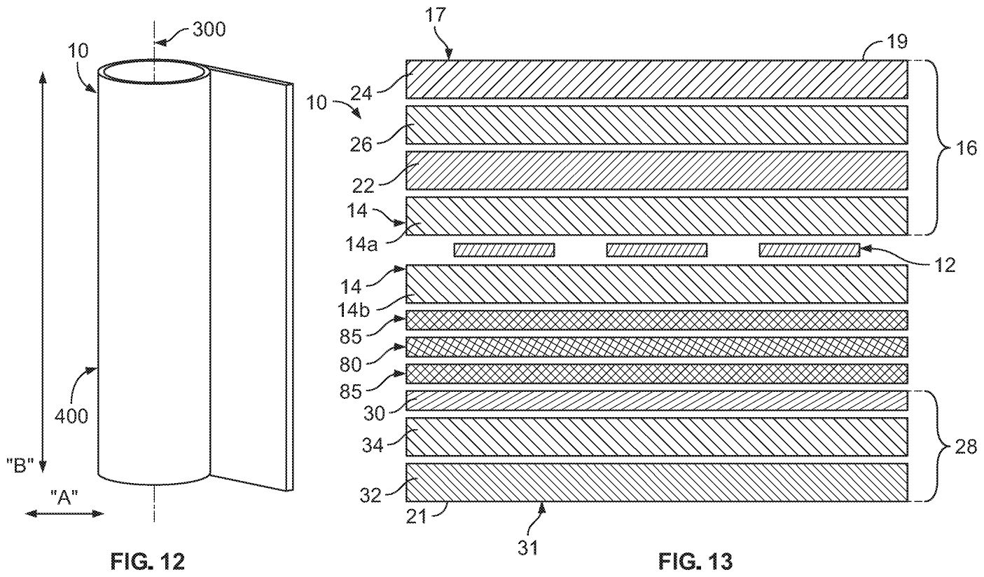

In some embodiments, as shown in FIG. 12, the photovoltaic module 10 may be in the form of a roll 400. In some embodiments, the photovoltaic module 10 may be rolled such that at least a portion of a surface 17 of the frontsheet 16 may be juxtaposed circumferentially with at least a portion of a surface 31 of the backsheet 28 when the photovoltaic module 10 is rolled upon itself. In some embodiments, the photovoltaic module 10 may be rolled such that at least a portion of a surface 17 of the frontsheet 16 contacts at least a portion of a surface 31 of the backsheet 28 when the photovoltaic module 10 is rolled upon itself. In some embodiments, when the photovoltaic module 10 is in the form of the roll 400, the photovoltaic module 10 may be rolled such that either the surface 17 of the frontsheet 16 faces outward, or the surface 31 of the backsheet 28 faces outward. In some embodiments, the surface 17 of the frontsheet 16 faces outward and is visible and accessible on the outside of the roll 400. In some embodiments, the surface 31 of the backsheet 28 faces outward.

In some embodiments, when the photovoltaic module 10 is the form of the roll 400, the roll 400 includes a separate core about which the photovoltaic module 10 is rolled. In some embodiments, when the photovoltaic module 10 is rolled around the core, the core may be of a material such as but not limited to paper, cardboard, wood, plastic, combinations of one or more of these materials, and/or another material. In some embodiments, the core is not included in the roll 400.

In some embodiments, in order for the photovoltaic module 10 to be in the form of the roll 400, a distance between adjacent solar cells 12, and/or a width of the solar cells 12, may be sized to permit at least a portion of the surface of the frontsheet 16 to be juxtaposed circumferentially with at least a portion of the surface of the backsheet 28. In some embodiments, the distances between adjacent ones of the solar cells 12, as well as the widths of the solar cells 12 may be measured in a same direction. For example, in some embodiments, as shown in FIGS. 11A and 11B, distances D may separate adjacent ones of the solar cells 12 from one another, where distances D are measured in a first direction A. In some embodiments, the solar cells 12 may have widths WS, where the widths WS are measured in the first direction A. In some embodiments, the distances D separating adjacent ones of the solar cells 12 may be the same as one another—that is, the solar cells 12 may be separated from one another by the same distance. In some embodiments, the distances D separating adjacent ones of the solar cells 12 may be different from one another—that is, two of the solar cells 12 may be separated from one another by a first distance, while two of the solar cells 12 may be separated from one another by a second, different distance, for example. In some embodiments, the widths WS of different ones of the solar cells 12, or all of the solar cells 12, may be the same as one another. In some embodiments, the widths of at least some of the solar cells 12 may be different from one another—that is, at least one solar cell 12 may have a first width, and at least one other solar cell 12 may have a second, different width. The width(s) WS may or may not be the same as the distance(s) D. Further, in some embodiments, although not illustrated in the drawings, when the photovoltaic module 10 is laminated, the encapsulant 14 may flow between the solar cells 12, such that the encapsulant 14 fully encapsulates the solar cells 12.

In some embodiments, one or more properties of one or more of the polymer layer 24, the first adhesive layer 26, the glass layer 22, the encapsulant 14, the first layer 30, the second adhesive layer 34, and/or the second layer 32 may be chosen so as to permit the photovoltaic module 10 to be in the form of the roll 400. These properties may include, for example, one or more thickness(es), and/or material(s) of the layers and adhesives.

In some embodiments, the solar cells 12 may be disposed within the photovoltaic module 10 such that the solar cells 12 are in the neutral plane of the photovoltaic module 10 when the photovoltaic module 10 is in the form of the roll 400. In some embodiments, when the photovoltaic module 10 is in the form of the roll 400 and the solar cells 12 are in the neutral plane, the solar cells 12 are under neither tension nor compression. In some embodiments, the solar cells 12 may be disposed within the photovoltaic module 10 such that the solar cells 12 are under either tension or under compression when the photovoltaic module 10 is in the form of the roll 400.

In some embodiments, as shown in FIG. 12, the roll 400 may define a longitudinal axis 300. In some embodiments, the longitudinal axis 300 of the roll 400 may extend in a second direction B that is perpendicular or substantially perpendicular to the first direction A in which the distance(s) between adjacent solar cells 12 and/or the width(s) of the solar cells 12 may be measured. Restated, the longitudinal axis 300 of the roll 400 may be parallel to or substantially parallel to the first direction A The second direction B, although not shown in FIG. 11A, for example, extends into and out the page. Length(s) of one or more of the solar cells 12 may be measured in the second direction B

As discussed, in some embodiments, the photovoltaic module 10 may be installed directly on the roof deck—that is, with no intervening membrane, member, component, structure, or other layer, such as the roofing membrane 70, between the roof deck and the photovoltaic module 10. In some embodiments, the photovoltaic module 10 may be installed on the roof deck by an adhesive, thermal bonding, ultrasonic welding, induction welding, hot air welding, mechanical crimping, and/or fasteners, as discussed. In some other embodiments, the photovoltaic module 10 may be installed indirectly on the roofing deck, such that there is one or more intervening layers, members, components, structures, layers, and/or membranes between the roof deck and the photovoltaic module 10.

In some embodiments, when the photovoltaic module 10 is in the form of the roll 400 as shown in FIG. 12, the method of installation may include obtaining the roll 400 of the photovoltaic module 10, as described, and unrolling the roll 400 of the photovoltaic module 10.

Referring to FIG. 13, in some embodiments, the photovoltaic module 10 includes a plurality of the solar cells 12, the encapsulant 14 encapsulating the solar cells 12, the frontsheet 16 juxtaposed with one surface of the encapsulant 14, and the backsheet 28 juxtaposed with another surface of the encapsulant 14. Any or all of the photovoltaic module 10, the solar cell 12, the encapsulant 14, the frontsheet 16, and/or the backsheet 28 may be as further described herein.

Also as shown in FIG. 13, in some embodiments, the photovoltaic module 10 may include a support layer 80, and/or may include a second encapsulant 85. In some embodiments, the support layer 80 may be juxtaposed with a surface of the encapsulant 14, as well as with a surface of the second encapsulant 85. In some embodiments, the other surface of the second encapsulant 85 may be juxtaposed with a surface of the backsheet 28. Any or all of the photovoltaic module 10, the solar cells 12, the encapsulant 14, the frontsheet 16, and/or the backsheet 28 may be as further described herein. In some embodiments, one or more properties of the second encapsulant 85 may be the same as or different than properties of the encapsulant 14, such as, for example, the described thickness(es), and the described material(s).

In some embodiments, one or more properties of the support layer 80 may be the same as or different than properties of any or all of the polymer layer 24, the first adhesive layer 26, the glass layer 22, the encapsulant 14, the first layer 30, the second adhesive 34, and/or the second layer 32, and/or the support member 275, such as, for example, the described thickness(es) and/or the described material(s). In some embodiments, the use of the second encapsulant 85 and/or the support layer 80 may increase a rigidity of the photovoltaic module 10 as compared to the photovoltaic module 10 where either or both of the support layer 80 and/or the second encapsulant 85 are omitted. In some embodiments, although the figure shows the photovoltaic module 10 with the support layer 80 and the second encapsulant 85 as including the backsheet 28 with the first layer 30, the second layer 32, and the second adhesive 34 attaching the first layer 30 and the second layer 32, the backsheet 28 need not include any or all of these layers. Thus, in some embodiments, the photovoltaic module 10 with the support layer 80 and the second encapsulant 85 may include the backsheet 28 with the first layer 30 and which omits the second layer 32 and the second adhesive layer 34 (that is, the backsheet 28 as shown in FIG. 11A, for example).

In some embodiments, any of the disclosed layers from any of the described embodiments may be combined with one or more layers from one or more of any of the other embodiments, for example, to provide the photovoltaic module 10 that includes or omits and of the disclosed layers. Further, any of the photovoltaic modules 10 may be in the form of a laminate.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

What is claimed is:

1. A roll, comprising:
a laminate, comprising:
a plurality of solar cells,
wherein the plurality of solar cells comprises:
a first solar cell,
a second solar cell, and
a third solar cell,
wherein the first solar cell and the second solar cell are separated in a first direction by a first distance,
wherein the second solar cell and the third solar cell are separated in the first direction by the first distance, and
wherein each of the first, second, and third solar cells comprises:
a width in the first direction, and
a length in a second direction,
wherein the second direction is perpendicular to the first direction;
a first encapsulant,
wherein the first encapsulant encapsulates the plurality of solar cells, and
wherein the first encapsulant includes a first surface and a second surface opposite the first surface;
a frontsheet,
wherein the frontsheet includes a first surface and a second surface opposite the first surface of the frontsheet,
wherein the second surface of the frontsheet is adjacent the first surface of the first encapsulant; and
a backsheet,
wherein the backsheet includes a first surface and a second surface opposite the first surface of the backsheet,
wherein the first surface of the backsheet is adjacent the second surface of the first encapsulant, and
wherein
the widths of the first, second, and third solar cells, and
the first and second distances
are sized to permit at least a portion of the first surface of the frontsheet to be juxtaposed circumferentially with at least a portion of the second surface of the backsheet.

2. The roll of claim 1, wherein the backsheet comprises a thermoplastic polyolefin.

3. The roll of claim 1, wherein the at least a portion of the frontsheet contacts the at least a portion of the backsheet.

4. The roll of claim 1, further comprising a longitudinal axis,
wherein the first direction is perpendicular to the longitudinal axis, and
wherein the second direction is parallel to the longitudinal axis.

5. The roll of claim 1, wherein the backsheet contacts the second surface of the first encapsulant.

6. The roll of claim 1, wherein the frontsheet contacts the first surface of the first encapsulant.

7. The roll of claim 1, wherein the frontsheet comprises a transparent material.

8. The roll of claim 7, wherein the transparent material comprises at least one of polymer and glass.

9. The roll of claim 1,
wherein the laminate further comprises:
a support layer,
wherein the support layer is adjacent the second surface of the first encapsulant; and
a second encapsulant,
wherein the second encapsulant is between the support layer and the backsheet.

10. The roll of claim 9, wherein each of the first and second encapsulants comprises a same material.

11. A method, comprising:
obtaining a roll, the roll comprising:
a laminate, comprising:
a plurality of solar cells,
wherein the plurality of solar cells comprises:
a first solar cell,
a second solar cell, and
a third solar cell,
wherein the first solar cell and the second solar cell are separated in a first direction by a first distance,
wherein the second solar cell and the third solar cell are separated in the first direction by the first distance, and
wherein each of the first, second, and third solar cells comprises:
a width in the first direction, and
a length in a second direction,
wherein the second direction is perpendicular to the first direction;
a first encapsulant,
wherein the first encapsulant encapsulates the plurality of solar cells, and
wherein the first encapsulant includes a first surface and a second surface opposite the first surface;
a frontsheet,
wherein the frontsheet includes a first surface and a second surface opposite the first surface of the frontsheet,
wherein the second surface of the frontsheet is adjacent the first surface of the first encapsulant; and
a backsheet,
wherein the backsheet includes a first surface and a second surface opposite the first surface of the backsheet,
wherein the first surface of the backsheet is adjacent the second surface of the first encapsulant, and
wherein
the widths of the first, second, and third solar cells, and
the first and second distances
are sized to permit at least a portion of the first surface of the frontsheet to be juxtaposed circumferentially with at least a portion of the second surface of the backsheet; and
unrolling the roll so as to install the laminate on a roof deck,
wherein the second surface of the backsheet is juxtaposed with a surface of the roof deck.

12. The method of claim 11, wherein the unrolling the roll comprises unrolling the roll so as to install the laminate directly on the roof deck without any intervening member between the laminate and the roof deck.

13. The method of claim 11, further comprising:
welding the laminate to the roof deck.

14. The method of claim 11, wherein the roof deck is a flat roof deck.

15. The method of claim 11, wherein the roof deck is a sloped roof deck.

16. The method of claim 11, wherein the backsheet comprises a thermoplastic polyolefin.

17. The method of claim 11, wherein the frontsheet comprises a transparent material.

18. The method of claim 17, wherein the transparent material comprises at least one of polymer and glass.

19. The method of claim 11,
wherein the laminate further comprises:
a support layer,
wherein the support layer is adjacent the second surface of the first encapsulant; and
a second encapsulant,
wherein the second encapsulant is between the support layer and the backsheet.

20. The method of claim 19, wherein each of the first and second encapsulants comprises a same material.
